(19) United States
(12) Patent Application Publication
(10) Pub. No.: US 2024/0186475 A1
(43) Pub. Date: Jun. 6, 2024

(54) DISPLAY DEVICE

(71) Applicant: LG Display Co., Ltd., Seoul (KR)

(72) Inventors: Yongmin JEONG, Seoul (KR); DaHye SHIM, Seoul (KR)

(73) Assignee: LG Display Co., Ltd., Seoul (KR)

(21) Appl. No.: 18/367,643

(22) Filed: Sep. 13, 2023

(30) Foreign Application Priority Data
Dec. 6, 2022 (KR) 10-2022-0168466

(51) Int. Cl. H01L 33/62; G09G 3/32; H01L 25/075; H01L 25/16; H01L 27/12

(52) U.S. Cl. CPC H01L 33/62; G09G 3/32; H01L 25/0753; H01L 25/167; H01L 27/124; H01L 27/1255; G09G 2310/0267; G09G 2320/0233

(57) ABSTRACT

A display device can include a lower substrate having an active area and a non-active area and being stretchable, a pattern layer disposed on the active area of the lower substrate and including a plurality of first plate patterns and a plurality of first line patterns, a plurality of pixels disposed on each of the first plate patterns, a plurality of connection lines disposed on the first line patterns and configured to connect the plurality of pixels, and a gate driver including a plurality of stages to supply a gate signal to the plurality of pixels through the plurality of connection lines. The gate driver can be disposed on the active area of the lower substrate.

### CROSS-REFERENCE TO RELATED APPLICATIONS

This application claims priority to Korean Patent Application No. 10-2022-0168466 filed on Dec. 6, 2022, in the Korean Intellectual Property Office, the entire disclosure of which is hereby expressly incorporated reference into the present application.

### BACKGROUND

### Field

The present disclosure relates to a display device, and more particularly to a stretchable display device which can be stretched.

### Discussion of the Related Art

As display devices are used for a monitor of a computer, a television, or a cellular phone, there are an organic light emitting display (OLED) device which is a self-emitting device and a liquid crystal display (LCD) device which requires a separate light source.

An applicable range of the display device is diversified to personal digital assistants as well as monitors of computers and televisions and a display device with a large display area and a reduced volume and weight is being studied.

Further, a display device which is manufactured by forming a display unit and a wiring line on a flexible substrate such as plastic being a flexible material so as to be stretchable in a specific direction and changed in various forms, is getting attention as a next generation display device.

### SUMMARY OF THE DISCLOSURE

An object to be achieved by the present disclosure is to provide a display device which minimizes a bezel area.

Another object to be achieved by the present disclosure is to provide a display device which improves a luminance uniformity.

Another object to be achieved by the present disclosure is to provide a display device has a high resolution and a large area.

Objects of the present disclosure are not limited to the above-mentioned objects, and other objects, which are not mentioned above, can be clearly understood by those skilled in the art from the following descriptions.

In order to achieve the above-described objects, according to an aspect of the present disclosure, a display device can include a lower substrate having an active area and a non-active area and being stretchable, a pattern layer disposed on the active area of the lower substrate and including a plurality of first plate patterns and a plurality of first line patterns, a plurality of pixels disposed on each of the first plate patterns, a plurality of connection lines disposed on the first line patterns and configured to connect the plurality of pixels, and a gate driver including a plurality of stages to supply a gate signal to the plurality of pixels through the connection lines. The gate driver can be disposed on the active area of the lower substrate.

Other detailed matters of the exemplary embodiments are included in the detailed description and the drawings.

According to the present disclosure, a gate driver included in a display device is formed in an active area in a gate-in array manner so that a bezel area of the display device can be minimized.

Further, the gate driver is disposed in an intermediate area of the active area in a gate-in array (GIA) manner so that the gate signal delay according to a relative location of the pixel is minimized to improve the luminance uniformity in the entire active area and implement a display device with a high resolution and a large area.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a plan view illustrating a display device according to an exemplary embodiment of the present disclosure;

FIG. 2 is an enlarged view of an example of a part A of FIG. 1;

FIG. 3 is a view for explaining an example of a placement relationship of connection lines included in the display device of FIG. 1;

FIG. 4 is a cross-sectional view illustrating an example taken along line III-III′ of FIG. 2;

FIG. 5 is a cross-sectional view illustrating an example taken along line IV-IV′ of FIG. 2;

FIG. 6 is a cross-sectional view illustrating an example taken along line V-V′ of FIG. 2;

FIG. 7 is a block diagram illustrating an example of a gate driver included in the display device of FIG. 1;

FIG. 8 is a circuit diagram illustrating an example of a stage included in the gate driver of FIG. 7;

FIG. 9 is a view for explaining an example of a placement relationship between configurations included in the gate driver of FIG. 7;

FIG. 10 is a cross-sectional view illustrating an example taken along line I-I′ of FIG. 9;

FIGS. 11A and 11B are cross-sectional views illustrating examples taken along line II-II′ illustrated in FIG. 9;

FIG. 12 is a block diagram illustrating another example of a gate driver included in the display device of FIG. 1;

FIG. 13 is a circuit diagram illustrating an example of a stage included in the gate driver of FIG. 12; and

FIG. 14 is a view for explaining an example of a placement relationship between configurations included in a gate driver of FIG. 12.

### DETAILED DESCRIPTION OF THE EMBODIMENTS

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

Further, the term “exemplary” can be interchangeably used with and means the term “example.”

When the position relation between two parts is described using the terms such as “on,” “above,” “over,” “below,” “under,” “next,” etc., one or more parts can be positioned between the two parts unless the terms are used with the term “immediately” or “directly”.

In the specification, when an element/layer is disposed “on” or “above” another element/layer (referred to as ‘two elements/layers’), one or more additional layers/elements can be interposed between the two elements/layers, or the two elements/layers can be directly on with respect to each other.

Although the terms “first”, “second”, and the like are used for describing various components, these components are not confined by these terms. These terms are merely used for distinguishing one component from the other components, and may not define order or sequence. Therefore, a first component to be mentioned below can be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings. All components of each display device according to all embodiments of the present disclosure are operatively coupled and configured.

A display device according to an exemplary embodiment of the present disclosure is a display device which is capable of displaying images even in a bent or extended state and can also be referred to as a stretchable display device, a flexible display device and an extendable display device. As compared with the general display devices of the related art, the display device can have not only a high flexibility, but also stretchability. Therefore, the user can bend or extend a display device and a shape of a display device can be freely changed in accordance with manipulation of a user. For example, when the user pulls the display device by holding ends of the display device, the display device can be extended to the pulling direction of the user. Alternatively, when the user disposes the display device on an outer surface which is not flat, the display device can be disposed to be bent in accordance with the shape of the outer surface of the wall. Further, when a force applied by the user is removed, the display device can return to its original shape.

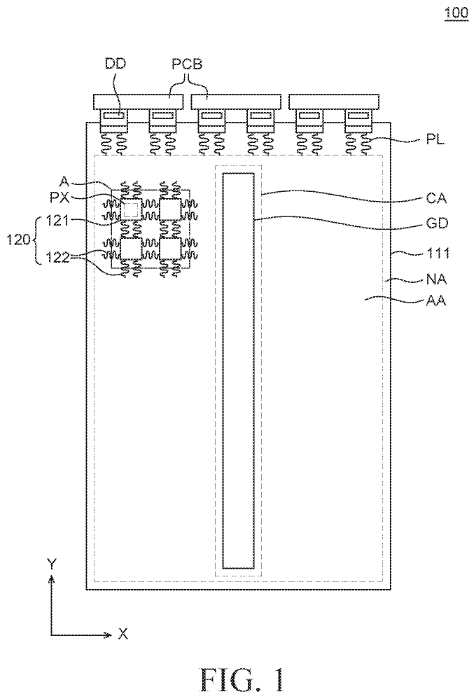

FIG. 1 is a plan view illustrating a display device according to an exemplary embodiment of the present disclosure.

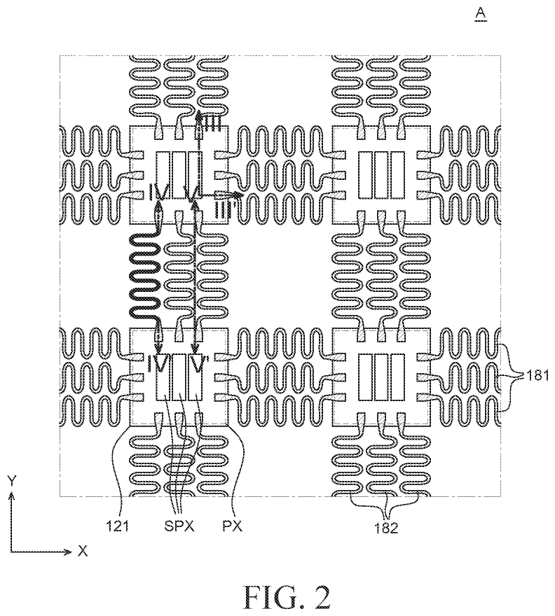

FIG. 2 is an enlarged view of an example of a part A of FIG. 1.

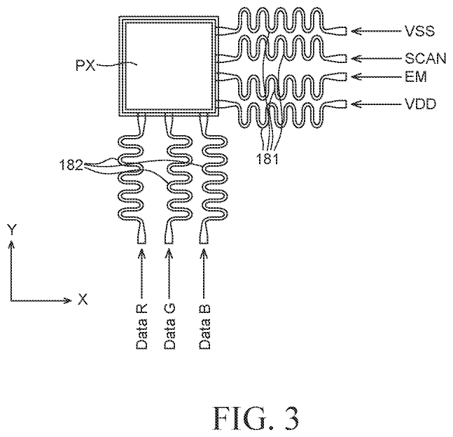

FIG. 3 is a view for explaining an example of a placement relationship of connection lines included in a display device of FIG. 1.

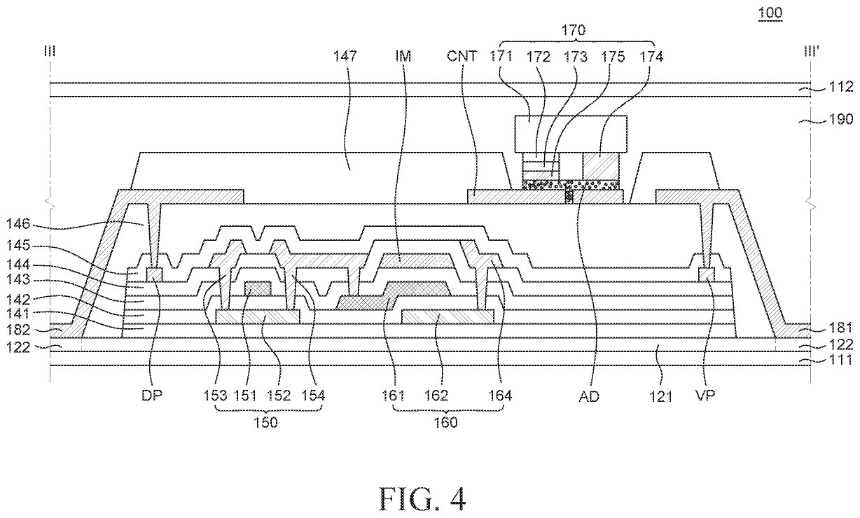

FIG. 4 is a cross-sectional view illustrating an example taken along line III-III′ of FIG. 2.

Referring to FIG. 1, a display device 100 according to an exemplary embodiment of the present disclosure can include a lower substrate 111, a pattern layer 120, a plurality of pixels PX, a gate driver GD, and a data driver DD. In the exemplary embodiment, referring to FIG. 4, the display device 100 can further include a filling layer 190 and an upper substrate 112.

The lower substrate 111 is a substrate which supports and protects several components of the display device 100. The upper substrate 112 is a substrate which covers and protects several components of the display device 100. For example, the lower substrate 111 is a substrate which supports the pattern layer 120 on which the pixels PX and the gate driver GD are formed. Further, the upper substrate 112 is a substrate which covers the pixels PX and the gate driver GD.

The lower substrate 111 and the upper substrate 112 which are flexible substrates can be configured by an insulating material which is bendable or extendable. For example, the lower substrate 111 and the upper substrate 112 can be formed of a silicon rubber such as polydimethylsiloxane (PDMS) or an elastomer such as polyurethane (PU) or polytetrafluoroethylene (PTFE). Accordingly, the lower substrate 111 and the upper substrate 112 can have flexibility. Depending on the exemplary embodiment, the materials of the lower substrate 111 and the upper substrate 112 can be the same, but are not limited thereto and can vary.

The lower substrate 111 and the upper substrate 112 are ductile substrates so as to be reversibly expandable and contractible. Accordingly, the lower substrate 111 can be referred to as a lower stretchable substrate, a lower stretching substrate, a lower extending substrate, a lower ductile substrate, a lower flexible substrate, a first stretchable substrate, a first stretching substrate, a first extending substrate, a first ductile substrate, or a first flexible substrate. The upper substrate 112 can be referred to as an upper stretchable substrate, an upper stretching substrate, an upper extending substrate, an upper ductile substrate, an upper flexible substrate, a second stretchable substrate, a second stretching substrate, a second extending substrate, a second ductile substrate, or a second flexible substrate. Further, moduli of elasticity of the lower substrate 111 and the upper substrate 112 can be several MPa to several hundreds of MPa. Further, a ductile breaking rate of the lower substrate 111 and the upper substrate 112 can be 100% or higher. Here, the ductile breaking rate refers to a stretching rate at a timing when an object to be stretched is broken or cracked. Further, a thickness of the lower substrate can be 10 μm to 1 mm, but is not limited thereto.

The lower substrate 111 can include an active area AA and a non-active area NA which encloses the active area AA. However, the active area AA and the non-active area are not mentioned to be limited to the lower substrate 111, but mentioned for the entire display device 100.

The active area AA can be an area in which images are displayed in the display device 100. A plurality of pixels PX can be disposed on the active area AA. Each pixel PX can include a display element and various driving elements for driving the display element. Various driving elements can refer to at least one thin film transistor (TFT) and a capacitor, but are not limited thereto. Further, the plurality of pixels PX can be connected to various wiring lines, respectively. For example, each of the plurality of pixels PX can be connected to various wiring lines, such as a gate line (for example, a scan signal line or an emission signal line), a data line, a high potential voltage line, a low potential voltage line, and an initialization voltage line.

The non-active area NA is an area where no image is displayed. The non-active area NA can be disposed to be adjacent to the active area AA. For example, the non-active area NA is an area which encloses the active area AA. However, it is not limited thereto so that the non-active area NA corresponds to an area excluding the active area AA from the lower substrate 111 and can be modified and separated in various forms. Components for driving a plurality of pixels PX disposed in the active area AA can be disposed on the non-active area NA. For example, a plurality of pads which is connected to the data driver DD can be disposed on the non-active area NA and each pad can be connected to the plurality of pixels PX of the active area AA through pad connection lines PL disposed on the non-active area NA.

A pattern layer 120 can be disposed on the lower substrate 111. In one exemplary embodiment, the pattern layer 120 can include a plurality of first plate patterns 121 and a plurality of line patterns 122 disposed in the active area AA.

The first plate patterns 121 can be disposed in the active area AA of the lower substrate 111. A plurality of pixels PX can be formed on the first plate patterns 121, respectively.

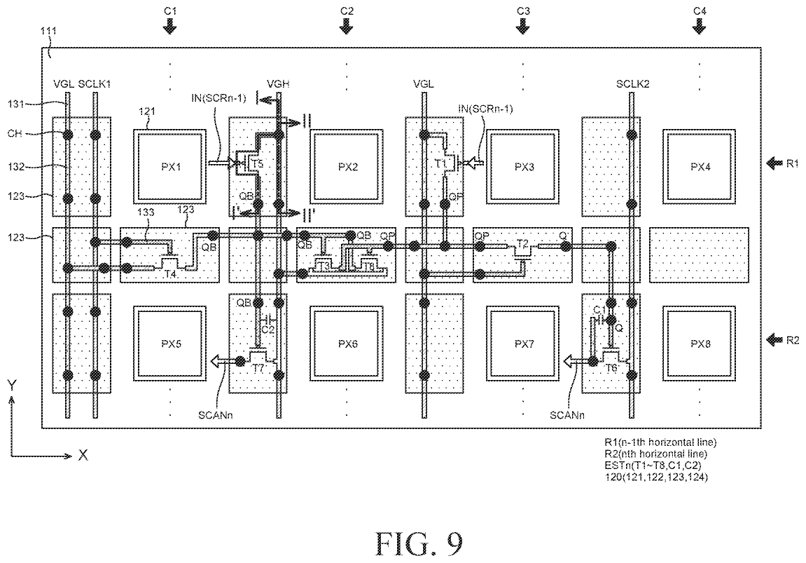

In the exemplary embodiment in FIG. 1, the pattern layer 120 can further include a plurality of second plate patterns 123 (see FIG. 9) disposed in the active area AA. On the second patterns, components (for example, transistors, capacitors, various connection signal lines, and the like) included in the gate driver GD can be disposed. This will be described in more detail with reference to FIGS. 9 to 11B.

Referring to FIGS. 1 to 4, the pattern layer 120 can further include the plurality of first line patterns 122 disposed in the active area AA.

The first line patterns 122 are patterns which are disposed in the active area AA and connect the first plate patterns 121 which are adjacent to each other and are referred to as first connection patterns. For example, at least one first line pattern 122 can be disposed between the first plate patterns 121.

In one exemplary embodiment, referring to FIG. 1, each of the first line patterns 122 have a wavy shape. For example, the first line patterns 122 can have a sinusoidal shape. However, it is just illustrative, so that the shape of the first line pattern 122 is not limited thereto. For example, each of the first line patterns 122 can have a zigzag shape. As another example, each of the first line patterns 122 can have various shapes, such as a plurality of rhombic substrates being connected and extending at vertices. As described above, the number and the shape of the plurality of first line patterns 122 illustrated in FIG. 1 are illustrative and the number and the shape of the plurality of first line patterns 122 can vary depending on the design.

In one exemplary embodiment, the first plate pattern 121 and the first line pattern 122 can be rigid patterns. For example, the first plate pattern 121 and the first line pattern 122 can be more rigid than the lower substrate 111 and the upper substrate 112. Accordingly, moduli of elasticity of the first plate pattern 121 and the first line pattern 122 can be higher than the modulus of elasticity of the lower substrate 111. The modulus of elasticity is a parameter representing a rate of deformation against the stress applied to the substrate and the higher the modulus of elasticity, the higher the hardness. Therefore, the first plate pattern 121 and the first line pattern 122 can be referred to as a first rigid pattern and a second rigid pattern. For example, moduli of elasticity of the first plate pattern 121 and the first line pattern 122 can be 1000 times higher than the modulus of elasticity of the lower substrate 111 and the upper substrate 112, but it is illustrative, and the exemplary embodiment of the present disclosure is not limited thereto.

In the exemplary embodiment, the first plate pattern 121 and the first line pattern 122 can include a plastic material having a lower flexibility than the lower substrate 111 and the upper substrate 112. For example, the first plate pattern 121 and the first line pattern 122 can include at least one of polyimide (PI), polyacrylate, and polyacetate.

According to the exemplary embodiment, the first plate pattern 121 and the first line pattern 122 can be formed of the same material, but are not limited thereto and can be formed of different materials. When the first plate pattern 121 and the first line pattern 122 are formed of the same material, the first plate pattern 121 and the first line pattern 122 can be integrally formed.

According to the exemplary embodiment, the lower substrate 111 can be defined to include a first lower pattern and a second lower pattern. The first lower pattern can be an area of the lower substrate 111 overlapping the first plate patterns 121 and the second lower pattern can be an area which does not overlap the first plate patterns 121.

Further, the upper substrate 112 can be defined to include a first upper patterns and a second upper pattern. The first upper pattern can be an area of the upper substrate 112 overlapping the first plate patterns 121 and the second upper pattern can be an area which does not overlap the first plate patterns 121.

At this time, moduli of elasticity of the first lower pattern and the first upper pattern can be higher than moduli of elasticity of the second lower pattern and the second upper pattern. For example, the first lower pattern and the first upper pattern are formed of the same material as the first plate pattern 121 and the second lower pattern and the second upper pattern can be formed of a material having a modulus of elasticity lower than the first plate pattern 121.

For example, the first lower pattern and the first upper pattern can be formed of polyimide (PI), polyacrylate, polyacetate, or the like. Further, the second lower pattern and the second upper pattern can be formed of silicon rubber such as polydimethylsiloxane (PDMS) or elastomer such as polyurethane (PU) or polytetrafluoroethylene (PTFE).

The gate driver GD can supply a gate signal to the pixels PX disposed in the active area AA.

In one exemplary embodiment, the gate driver GD can be disposed in the active area (a center area CA of the active area AA). For example, the gate driver GD can be mounted on the second plate pattern 123 (see FIG. 9) disposed on the active area AA of the lower substrate 111 described above. The gate driver GD can be formed on the second plate pattern 123 (see FIG. 9) in a gate in array (GIA) manner. Therefore, various circuit configurations which configure the gate driver GD, such as various transistors, capacitors, and signal lines, can be disposed on the plurality of second plate patterns 123 (see FIG. 9).

The gate driver GD includes a plurality of stages formed on the plurality of second plate patterns 123 (see FIG. 9) and each stage included in the gate driver GD can be electrically connected to each other by means of the plurality of gate connection lines. Accordingly, a gate signal output from any one of stages can be transmitted to the other stage. Further, each stage can sequentially supply the gate signal to the plurality of pixels PX connected to each stage.

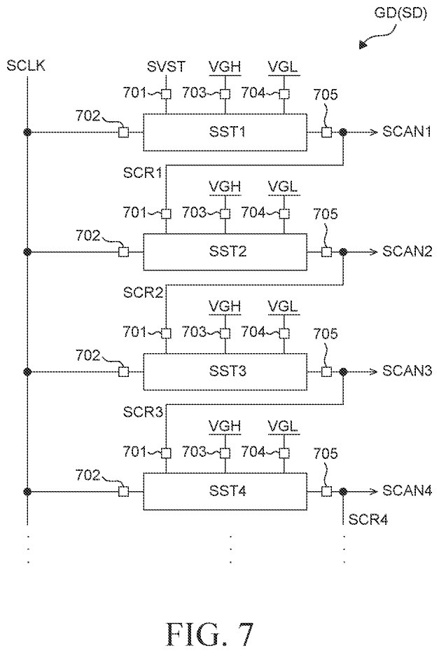

A specific configuration of the gate driver GD and a placement relationship of components included in the gate driver GD will be described in more detail with reference to FIGS. 7 to 9.

The printed circuit board PCB can transmit signals and voltages for driving the display element from the control unit to the display element. Therefore, the printed circuit board PCB can also be referred to as a driving substrate. A control unit such as an IC chip or a circuit unit can be mounted on the printed circuit board PCB. Further, on the printed circuit board PCB, a memory or a processor can also be mounted. Further, the printed circuit board PCB provided in the display device 100 can include a stretching area and a non-stretching area to ensure stretchability. Further, in the non-stretching area, an IC chip, a circuit unit, a memory, and a processor are mounted and in the stretching area, wiring lines which are electrically connected to the IC chip, the circuit unit, the memory, and the processor can be disposed.

The data driver DD can supply a data signal to the plurality of pixels PX disposed in the active area AA. The data driver DD is configured as an IC chip so that it can be also referred to as a data integrated circuit D-IC. Further, the data driver DD can be mounted in the non-stretching area of the printed circuit board PCB. For example, the data driver DD can be mounted on the printed circuit board PCB in the form of a chip on board (COB). Even though in FIG. 1, it is illustrated that the data driver DD is mounted in a chip on film (COF) manner, it is not limited thereto and the data driver DD can be mounted by a chip on board (COB), a chip on glass (COG), or a tape carrier package (TCP) manner.

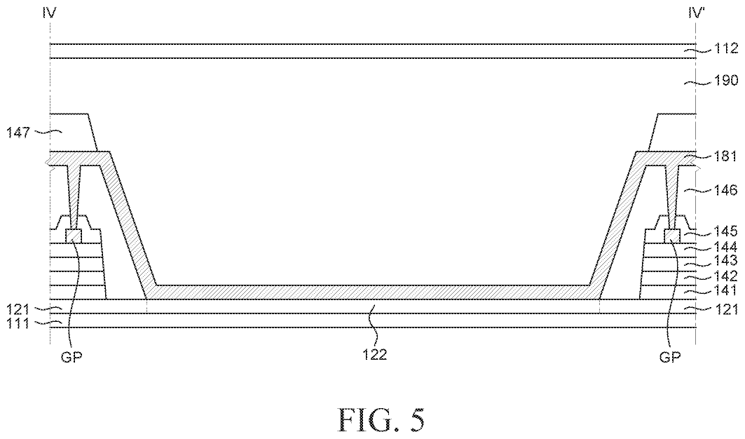

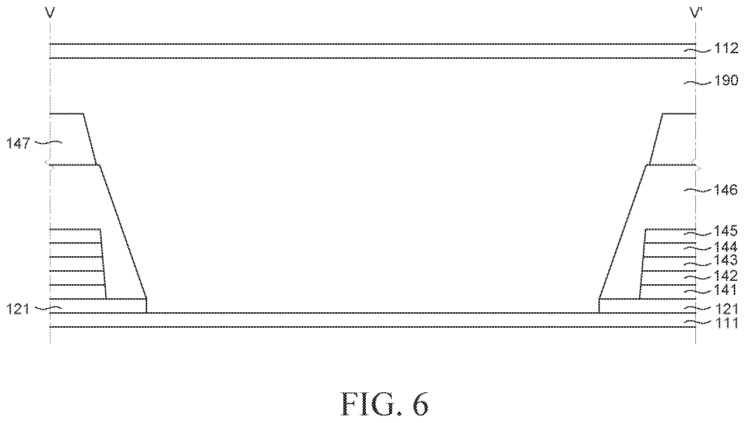

Hereinafter, the active area AA of the display device 100 according to the exemplary embodiment of the present disclosure will be described in more detail with reference to FIGS. 5 and 6 together.

FIG. 5 is a cross-sectional view illustrating an example taken along line IV-IV′ of FIG. 2.

FIG. 6 is a cross-sectional view illustrating an example taken along line V-V′ of FIG. 2.

For the convenience of description, the description will be made with reference to FIGS. 1 to 4 together.

Referring to FIGS. 1 and 2, the plurality of first plate patterns 121 can be disposed on the lower substrate 111 in the active area AA. The first plate patterns 121 are spaced apart from each other to be disposed on the lower substrate 111. For example, as illustrated in FIGS. 1 and 2, the first plate patterns 121 can be disposed on the lower substrate 111 in a matrix, but this is just illustrative, but the exemplary embodiment of the present disclosure is not limited thereto.

Referring to FIGS. 2 and 4, a pixel PX including the plurality of sub pixels SPX can be disposed on the first plate pattern 121. Each of the sub pixels SPX can include an LED 170 which is a display element and a driving transistor 160 and a switching transistor 150 which drive the LED 170. However, in the sub pixel SPX, the display element is not limited to an LED, and can also be changed to an organic light emitting diode. Further, the sub pixels SPX can include a red sub pixel, a green sub pixel, and a blue sub pixel, but is not limited thereto and colors of the sub pixels SPX can be modified to various colors as needed.

The sub pixels SPX can be connected to a plurality of connection lines 181 and 182. For example, the sub pixels SPX can be electrically connected to the first connection line 181 extending in the first direction X and the sub pixels SPX can be electrically connected to the second connection line 182 extending in the second direction Y.

In one exemplary embodiment, connection lines 181 and 182 connected to the sub pixels SPX can include various wiring lines, such as a gate line (for example, a scan signal line or an emission signal line), a data line, a high potential voltage line, a low potential voltage line, and an initialization voltage line.

For example, further referring to FIG. 3, in the display device 100 according to the exemplary embodiment of the present disclosure, four first connection lines 181 which are connected to one pixel PX are necessary and four second connection lines 182 which are connected to one pixel PX can be necessary.

Specifically, four first connection lines 181 can be a scan signal line which transmits a scan signal SCAN, an emission signal line which transmits an emission signal EM, a low potential voltage line which transmits the low potential voltage VSS, and a high potential voltage line which transmits the high potential voltage VDD. Further, four second connection lines 182 can be an initialization voltage line which transmits an initialization voltage Vini, a red data line which transmits a red data signal Data_R, a green data line which transmits a green data signal Data_G, and a blue data line which transmits a blue data signal Data_B.

Hereinafter, a cross-sectional structure of the active area AA will be described in more detail with reference to FIGS. 4 to 6. In the meantime, for the convenience of description, in FIGS. 4 to 6, cross-sectional structures of the pixel PX, the first plate pattern 121, the first line pattern 122, and connection lines 181 and 182, among the cross-sectional structures of the active area AA, are illustrated. The second plate pattern 123 (see FIG. 9) disposed on the active area AA which has been described with reference to FIG. 1 and a cross-sectional structure of the gate driver GD which is formed on the second plate pattern 123 (see FIG. 9) in the gate in array (GIA) manner will be described in more detail with reference to FIGS. 9 to 11B.

Referring to FIGS. 1 to 4, an inorganic insulating layer can be disposed on the plurality of first plate patterns 121. For example, the inorganic insulating layer can include a buffer layer 141, a gate insulating layer 142, a first interlayer insulating layer 143, a second interlayer insulating layer 144, and a passivation layer 145. However, the exemplary embodiment of the present disclosure is not limited thereto and various inorganic insulating layers are additionally disposed on the first plate patterns 121. At least one of the buffer layer 141, the gate insulating layer 142, the first interlayer insulating layer 143, the second interlayer insulating layer 144, and the passivation layer 145 which are inorganic insulating layers can be omitted.

To be more specific, the buffer layer 141 can be disposed on the first plate patterns 121. The buffer layer 141 can be formed on the plurality of first plate patterns 121 to protect various components of the display device 100 from permeation of moisture (H₂O) and oxygen (O₂) from the outside of the lower substrate 111 and the plurality of first plate patterns 121. The buffer layer 141 can be configured by an insulating material. For example, the buffer layer 141 can be configured by a single layer or a double layer formed of at least one of silicon nitride (SiNx), silicon oxide (SiOx), and silicon oxynitride (SiON). However, the buffer layer 141 can be omitted depending on a structure or a characteristic of the display device 100.

In one exemplary embodiment, the buffer layer 141 can be formed only in an area where the lower substrate 111 overlaps the first plate patterns 121 which has been described with reference to FIG. 1 and the second plate patterns 123 (see FIG. 9). As described above, the buffer layer 141 can be formed of an inorganic material so that the buffer layer 141 can be easily cracked or damaged during a process of stretching the display device 100. Therefore, the buffer layer 141 is not formed in an area between the first plate patterns 121 and the second plate patterns 123 (see FIG. 9). Instead, the buffer layer 141 is patterned to have a shape of the first plate patterns 121 and the second plate patterns 123 (see FIG. 9) to be disposed only above the first plate patterns 121 and the second plate patterns 123 (see FIG. 9). Therefore, in the display device 100 according to the exemplary embodiment of the present disclosure, the buffer layer 141 is formed only in an area overlapping the first plate patterns 121 and the second plate patterns 123 (see FIG. 9) which are rigid patterns. Therefore, even though the display device 100 is bent or extended to be deformed, the damage of various components of the display device 100 can be suppressed.

A switching transistor 150 including a gate electrode 151, an active layer 152, a source electrode 153, and a drain electrode 154 and a driving transistor 160 including a gate electrode 161, an active layer 162, a source electrode and a drain electrode 164 can be formed on the buffer layer 141.

First, the active layer 152 of the switching transistor 150 and the active layer 162 of the driving transistor 160 can be disposed on the buffer layer 141. For example, the active layer 152 of the switching transistor 150 and the active layer 162 of the driving transistor 160 can be formed of oxide semiconductors. Alternatively, the active layer 152 of the switching transistor 150 and the active layer 162 of the driving transistor 160 can be formed of amorphous silicon (a-Si), polycrystalline silicon (poly-Si), an organic semiconductor, or the like.

The gate insulating layer 142 can be disposed on the active layer 152 of the switching transistor 150 and the active layer 162 of the driving transistor 160. The gate insulating layer 142 electrically insulates the gate electrode 151 of the switching transistor 150 from the active layer 152 of the switching transistor 150 and can electrically insulate the gate electrode 161 of the driving transistor 160 from the active layer 162 of the driving transistor 160. The gate insulating layer 142 can include an insulating material. For example, the gate insulating layer 142 can be configured by a single layer of silicon nitride (SiNx) or silicon oxide (SiOx) which is an inorganic material or a plurality of layers of silicon nitride (SiNx) or silicon oxide (SiOx), but it is not limited thereto.

The gate electrode 151 of the switching transistor 150 and the gate electrode 161 of the driving transistor 160 can be disposed on the gate insulating layer 142. The gate electrode 151 of the switching transistor 150 and the gate electrode 161 of the driving transistor 160 can be disposed on the gate insulating layer 142 to be spaced apart from each other. Further, the gate electrode 151 of the switching transistor 150 overlaps the active layer 152 of the switching transistor 150 and the gate electrode 161 of the driving transistor 160 can overlap the active layer 162 of the driving transistor 160.

The gate electrode 151 of the switching transistor 150 and the gate electrode 161 of the driving transistor 160 can be any one of various metal materials such as molybdenum (Mo), aluminum (Al), chrome (Cr), gold (Au), titanium (Ti), nickel (Ni), neodymium (Nd), and copper (Cu) or an alloy of two or more of them, or a plurality of layers thereof, but it is not limited thereto.

The first interlayer insulating layer 143 can be disposed on the gate electrode 151 of the switching transistor 150 and the gate electrode 161 of the driving transistor 160. The first interlayer insulating layer 143 can insulate the gate electrode 161 of the driving transistor 160 from an intermediate metal layer IM. The first interlayer insulating layer 143 can be formed of an inorganic material, similarly to the buffer layer 141. For example, the first interlayer insulating layer 143 can be configured by a single layer of silicon nitride (SiNx) or silicon oxide (SiOx) which is an inorganic material or a plurality of layers of silicon nitride (SiNx) or silicon oxide (SiOx), but it is not limited thereto.

The intermediate metal layer IM can be disposed on the first interlayer insulating layer 143. The intermediate metal layer IM can overlap the gate electrode 161 of the driving transistor 160. Therefore, a capacitor (for example, a storage capacitor) can be formed in an overlapping area of the intermediate metal layer IM and the gate electrode 161 of the driving transistor 160. Specifically, the storage capacitor can be formed by the gate electrode 161 of the driving transistor 160, the first interlayer insulating layer 143, and the intermediate metal layer IM. However, the placement area of the intermediate metal layer IM is not limited thereto and the intermediate metal layer IM overlaps the other electrode to form the storage capacitor in various forms.

The intermediate metal layer IM can be any one of various metal materials, for example, any one of molybdenum (Mo), aluminum (Al), chrome (Cr), gold (Au), titanium (Ti), nickel (Ni), neodymium (Nd), and copper (Cu) or an alloy of two or more of them, or a plurality of layers thereof, but it is not limited thereto.

The second interlayer insulating layer 144 can be disposed on the intermediate metal layer IM. The second interlayer insulating layer 144 can insulate the gate electrode 151 of the switching transistor 150 from the source electrode 153 and the drain electrode 154 of the switching transistor 150. Further, the second interlayer insulating layer 144 can insulate the intermediate metal layer IM from the source electrode and the drain electrode 164 of the driving transistor 160. The second interlayer insulating layer 144 can be formed of an inorganic material, similarly to the buffer layer 141. For example, the first interlayer insulating layer 143 can be configured by a single layer of silicon nitride (SiNx) or silicon oxide (SiOx) which is an inorganic material or a plurality of layers of silicon nitride (SiNx) or silicon oxide (SiOx), but it is not limited thereto.

The source electrode 153 and the drain electrode 154 of the switching transistor 150 can be disposed on the second interlayer insulating layer 144. Further, the source electrode and the drain electrode 164 of the driving transistor 160 can be disposed on the second interlayer insulating layer 144. The source electrode 153 and the drain electrode 154 of the switching transistor 150 are disposed on the same layer to be spaced apart from each other. In the meantime, even though in FIG. 4, the source electrode of the driving transistor 160 is omitted, the source electrode of the driving transistor 160 can be also disposed to be spaced apart from the drain electrode 164 on the same layer. In the switching transistor 150, the source electrode 153 and the drain electrode 154 can be in contact with the active layer 152 to be electrically connected to the active layer 152. Further, in the driving transistor 160, the source electrode and the drain electrode 164 can be in contact with the active layer 162 to be electrically connected to the active layer 162. Further, the drain electrode 154 of the switching transistor 150 is in contact with the gate electrode 161 of the driving transistor 160 through a contact hole to be electrically connected to the gate electrode 161 of the driving transistor 160.

The source electrode 153 and the drain electrodes 154 and 164 can include any one of various metal materials such as molybdenum (Mo), aluminum (Al), chrome (Cr), gold (Au), titanium (Ti), nickel (Ni), neodymium (Nd), and copper (Cu) or an alloy of two or more of them, or a plurality of layers thereof, but it is not limited thereto.

Further, in this specification, even though it is described that the driving transistor 160 has a coplanar structure, various transistors such as a staggered structure can also be used. Further, in this specification, the transistor can be formed not only to have a top gate structure, but also to have a bottom gate structure.

A gate pad GP and a data pad DP can be disposed on the second interlayer insulating layer 144.

Specifically, referring to FIG. 5, the gate pad GP can be a pad which transmits a gate signal to the plurality of sub pixels SPX. The gate pad GP can be connected to the first connection line 181 through a contact hole. Further, the gate signal supplied from the first connection line 181 can be transmitted to the gate electrode 151 of the switching transistor 150 from the gate pad GP through a wiring line formed on the first plate pattern 121.

Referring to FIG. 4 again, the data pad DP can be a pad which transmits a data signal to the plurality of sub pixels SPX. The data pad DP can be connected to the second connection line 182 through a contact hole. Further, the data signal supplied from the second connection line 182 can be transmitted to the source electrode 153 of the switching transistor 150 from the data pad DP through a wiring line formed on the first plate pattern 121.

The voltage pad VP can be a pad which transmits a low potential voltage to the sub pixels SPX. The voltage pad VP can be connected to the first connection line 181 through a contact hole. Further, the low potential voltage supplied from the first connection line 181 can be transmitted to the n-electrode 174 of the LED 170 from the voltage pad VP through a wiring line formed on the first plate pattern 121.

The gate pad GP and the data pad DP can be formed of the same material as the source electrode 153 and the drain electrodes 154 and 164, but are not limited thereto.

The passivation layer 145 can be formed on the switching transistor 150 and the driving transistor 160. For example, the passivation layer 145 covers the switching transistor 150 and the driving transistor 160 to protect the switching transistor 150 and the driving transistor 160 from the permeation of moisture and oxygen. The passivation layer 145 can be formed of an inorganic material and configured by a single layer or a double layer, but is not limited thereto.

Further, the gate insulating layer 142, the first interlayer insulating layer 143, the second interlayer insulating layer 144, and the passivation layer 145 are patterned to be formed only in an area overlapping the plurality of first plate patterns 121. The gate insulating layer 142, the first interlayer insulating layer 143, the second interlayer insulating layer 144, and the passivation layer 145 are also formed of the inorganic material, similar to the buffer layer 141. Therefore, the gate insulating layer 142, the first interlayer insulating layer 143, the second interlayer insulating layer 144, and the passivation layer 145 can also be easily cracked to be damaged during the process of stretching the display device 100. Therefore, the gate insulating layer 142, the first interlayer insulating layer 143, the second interlayer insulating layer 144, and the passivation layer 145 are not formed in an area between the plurality of first plate patterns 121. However, the gate insulating layer 142, the first interlayer insulating layer 143, the second interlayer insulating layer 144, and the passivation layer 145 are patterned to have a shape of the plurality of first plate patterns 121 to be formed only above the first plate patterns 121.

The planarization layer 146 can be formed on the passivation layer 145. The planarization layer 146 can planarize upper portions of the switching transistor 150 and the driving transistor 160. The planarization layer 146 can be configured by a single layer or a plurality of layers and can be formed of an organic material. Therefore, the planarization layer 146 can also be referred to as an organic insulating layer. For example, the planarization layer 146 can be formed of an acrylic-based organic material, but is not limited thereto.

The planarization layer 146 can be disposed so as to cover top surfaces and side surfaces of the buffer layer 141, the gate insulating layer 142, the first interlayer insulating layer 143, the second interlayer insulating layer 144, and the passivation layer 145 on the plurality of first plate patterns 121. Further, the planarization layer 146 can enclose the buffer layer 141, the gate insulating layer 142, the first interlayer insulating layer 143, the second interlayer insulating layer 144, and the passivation layer 145 together with the plurality of first plate patterns 121. To be more specific, the planarization layer 146 can be disposed so as to cover a top surface and a side surface of the passivation layer 145, a side surface of the first interlayer insulating layer 143, a side surface of the second interlayer insulating layer 144, a side surface of the gate insulating layer 142, a side surface of the buffer layer 141, and a part of a top surface of the plurality of first plate patterns 121. Accordingly, the planarization layer 146 can supplement a step on side surfaces of the buffer layer 141, the gate insulating layer 142, the first interlayer insulating layer 143, the second interlayer insulating layer 144, and the passivation layer 145. Further, the planarization layer 146 can enhance an adhesive strength of the connection lines 181 and 182 disposed on a side surface of the planarization layer 146.

As illustrated in FIG. 4, an inclination angle of the side surface of the planarization layer 146 can be smaller than an inclination angle formed by side surfaces of the buffer layer 141, the gate insulating layer 142, the first interlayer insulating layer 143, the second interlayer insulating layer 144, and the passivation layer 145. For example, the side surface of the planarization layer 146 can have a slope which is gentler than a slope formed by the side surface of the passivation layer 145, the side surface of the first interlayer insulating layer 143, the side surface of the second interlayer insulating layer 144, the side surface of the gate insulating layer 142, and the side surface of the buffer layer 141. Therefore, the connection lines 181 and 182 which are disposed to be in contact with the side surface of the planarization layer 146 are disposed with a gentle slope so that when the display device 100 is stretched, the stress generated in the connection lines 181 and 182 can be reduced. Further, the side surface of the planarization layer 146 has a relatively gentle slope so that the crack of the connection lines 181 and 182 or separation thereof from the side surface of the planarization layer 146 can be suppressed.

Referring to FIGS. 2 to 5, the connection lines 181 and 182 refer to wiring lines which electrically connect the pads on the first plate patterns 121. The connection lines 181 and 182 can be disposed on the first line patterns 122. Further, the connection lines 181 and 182 can extend also onto the first plate patterns 121 to be electrically connected to the gate pad GP and the data pad DP on the first plate patterns 121. In the meantime, the first line pattern 122 is not disposed in an area where the connection lines 181 and 182 are not disposed, among areas between the plurality of first plate patterns 121.

The connection lines 181, 182 can include a first connection line 181 and a second connection line 182. The first connection line 181 and the second connection line 182 can be disposed between the plurality of first plate patterns 121. Specifically, the first connection line 181 refers to a wiring line extending in a first direction X between the first plate patterns 121, among the connection lines 181 and 182. The second connection line 182 can refer to a wiring line extending in a second direction Y between the first plate patterns 121, among the connection lines 181 and 182.

The connection lines 181 and 182 can be formed of a metal material such as copper (Cu), aluminum (Al), titanium (Ti), and molybdenum (Mo) or a stacked structure of metal materials such as copper/molybdenum-titanium (Cu/Moti) or titanium/aluminum/titanium (Ti/Al/Ti), but is not limited thereto.

In the case of a display panel of a general display device, various wiring lines such as a plurality of gate lines and a plurality of data lines are disposed to extend between the plurality of sub pixels as a straight line and the plurality of sub pixels is connected to one signal line. Therefore, in the display panel of the general display device, various wiring lines, such as a gate line, a data line, a high potential voltage line, and a reference voltage line, can extend from one side to the other side of the display panel of the organic light emitting display device without being disconnected on the substrate.

In contrast, in the display device 100 according to the exemplary embodiment of the present disclosure, various wiring lines, such as a gate line, a data line, a high potential voltage line, a reference voltage line, or an initialization voltage line having a straight line shape which are considered to be used for the display panel of the general display device, can be disposed only on the first plate patterns 121 and the second plate patterns 123 (see FIG. 9). For example, in the display device 100 according to the exemplary embodiment of the present disclosure, a linear wiring line can be disposed only on the first plate patterns 121 and the second plate patterns 123 (see FIG. 9).

In the display device 100 according to the exemplary embodiment of the present disclosure, the pads on the two adjacent first plate patterns 121 can be connected by the connection lines 181 and 182. Accordingly, the connection lines 181 and 182 can electrically connect the gate pads GP or the data pads DP on two adjacent first plate patterns 121. As described above, the display device 100 according to the exemplary embodiment of the present disclosure can include a plurality of connection lines 181 and 182 which electrically connects various wiring lines, such as a gate line, a data line, a high potential voltage line, and a reference voltage line, between the plurality of first plate patterns 121. For example, the gate line can be disposed on the plurality of first plate patterns 121 disposed to be adjacent to each other in the first direction X and the gate pad GP can be disposed on both ends of the gate line. At this time, each of the gate pads GP on the plurality of first plate patterns 121 adjacent to each other in the first direction X can be connected to each other by the first connection line 181 which serves as a gate line. Therefore, the gate line disposed on the first plate patterns 121 and the first connection line 181 disposed on the first line pattern 122 can serve as one gate line. The above-described gate line can be referred to as a scan signal line or an emission signal line. Further, wiring lines which extend in the first direction X, among all various wiring lines which can be included in the display device 100, such as a low potential voltage line and a high potential voltage line, can also be electrically connected by the first connection line 181, as described above.

Referring to FIGS. 2, 3, and 5, the first connection lines 181 can connect the gate pads GP on two first plate patterns 121 which are disposed side by side, among the gate pads GP on the plurality of first plate patterns 121 disposed to be adjacent in the first direction X. The first connection line 181 can serve as a gate line (for example, a scan signal line or an emission signal line), a high potential voltage line, or a low potential voltage line, but is not limited thereto. The gate pads GP on the plurality of first plate patterns 121 disposed in the first direction X can be connected by the first connection line 181 serving as a gate line and transmit one gate signal.

Further, referring to FIGS. 2, 3, and 4, the second connection line 182 can connect the data pads DP on two first plate patterns 121 which are disposed side by side, among the data pads DP on the plurality of first plate patterns 121 disposed to be adjacent in the second direction Y. The second connection line 182 can serve as a data line, a high potential voltage line, a low potential voltage line, or a reference voltage line, but is not limited thereto. The internal line on the plurality of first plate patterns 121 disposed in the second direction Y can be connected by the second connection lines 182 serving as a data line and transmit one data signal.

As illustrated in FIG. 5, the first connection line 181 can be disposed to be in contact with a top surface and a side surface of the planarization layer 146 disposed on the first plate pattern 121. Further, the first connection line 181 can be formed to extend onto the top surface of the first line pattern 122. Further, the second connection line 182 can be disposed to be in contact with a top surface and a side surface of the planarization layer 146 disposed on the first plate pattern 121. Further, the second connection line 182 can be formed to extend onto the top surface of the first line pattern 122.

However, as illustrated in FIG. 6, there is no need to dispose a rigid pattern in an area where the first connection line 181 and the second connection line 182 are not disposed. Therefore, the first line pattern 122 which is a rigid pattern may not be disposed below the first connection line 181 and the second connection line 182.

In the meantime, referring to FIG. 4, a bank 147 can be formed on the connection pad CNT, the connection lines 181 and 182, and the planarization layer 146. The bank 147 can be a component which divides adjacent sub pixels SPX. The bank 147 can be disposed so as to cover at least a part of the connection pad CNT, the connection lines 181 and 182, and the planarization layer 146. The bank 147 can be formed of an insulating material. Further, the bank 147 can include a black material. The bank 147 includes the black material to block wiring lines which can be visible through the active area AA. For example, the bank 147 can be formed of a carbon based mixture and for example, include carbon black. However, it is not limited thereto and the bank 147 can be formed of a transparent insulating material. In the meantime, even though in FIG. 4, it is illustrated that a height of the bank 147 is lower than a height of the LED 170, this is just illustrative, so that the exemplary embodiment of the present disclosure is not limited thereto and the height of the bank 147 can be equal to the height of the LED 170.

Referring to FIG. 4, the LED 170 can be disposed on the connection pad CNT and the first connection line 181. The LED 170 can include an n-type layer 171, an active layer 172, a p-type layer 173, an n-electrode 174, and a p-electrode 175. The LED 170 of the display device 100 according to the exemplary embodiment of the present disclosure can have a flip-chip structure in which the n-electrode 174 and the p-electrode 175 are formed on one surface.

The n-type layer 171 can be formed by injecting an n-type impurity into gallium nitride (GaN) having excellent crystallinity. The n-type layer 171 can be disposed on a separate base substrate which is formed of a material which is capable of emitting light.

The active layer 171 can be disposed on the n-type layer 172. The active layer 172 is a light emitting layer which emits light in the LED 170 and can be formed of a nitride semiconductor, for example, indium gallium nitride (InGaN). The p-type layer 173 can be disposed on the active layer 173. The p-type layer 173 can be formed by injecting a p-type impurity into gallium nitride (GaN).

As described above, the LED 170 according to the exemplary embodiment of the present disclosure can be manufactured by sequentially laminating the n-type layer 171, the active layer 172, and the p-type layer 173, and then etching a predetermined part to form the n-electrode 174 and the p-electrode 175. In this case, a predetermined part is a space for separating the n-electrode 174 and the p-electrode 175 from each other and the predetermined part can be etched to expose a part of the n-type layer 171. In other words, the surfaces of the LED 170 on which the n-electrode 174 and the p-electrode 175 are disposed are not flat surfaces, but have different heights.

As described above, the n-electrode 174 is disposed in the etched area and can be formed of a conductive material. Further, the p-electrode 175 is disposed in an area which is not etched and can also be formed of a conductive material. For example, the n-electrode 174 is disposed on the n-type layer 171 which is exposed by the etching process and the p-electrode 175 can be disposed on the p-type layer 173. The p-electrode 175 can be formed of the same material as the n-electrode 174.

An adhesive layer AD is disposed on top surfaces of the connection pad CNT and the first connection line 181 and between the connection pad CNT and the first connection line 181 so that the LED 170 can be adhered onto the connection pad CNT and the first connection line 181. At this time, the n-electrode 174 is disposed on the first connection line 181 and the p-electrode 175 can be disposed on the connection pad CNT.

The adhesive layer AD can be a conductive adhesive layer in which conductive balls are dispersed in an insulating base member. Therefore, when heat or a pressure is applied to the adhesive layer AD, the conductive balls are electrically connected in a portion applied with the heat or pressure to have a conductive property and an area which is not pressurized can have an insulation property. For example, the n-electrode 174 is electrically connected to the first connection line 181 by means of the adhesive layer AD and the p-electrode 175 can be electrically connected to the connection pad CNT by means of the adhesive layer AD. After applying the adhesive layer AD onto the top surface of the first connection line 181 and the connection pad CNT by an inkjet method, the LED 170 is transferred onto the adhesive layer AD and is pressurized and heated. By doing this, the connection pad CNT can be electrically connected to the p-electrode 175 and the first connection line 181 can be electrically connected to the n-electrode 174. However, the remaining part of the adhesive layer AD excluding a part of the adhesive layer AD disposed between the n-electrode 174 and the first connection pad 181 and a part of the adhesive layer AD disposed between the p-electrode 175 and the connection pad CNT can have an insulation property. In the meantime, the adhesive layer AD can be divided to be disposed on the connection pad CNT and the first connection line 181, respectively.

Further, the connection pad CNT is electrically connected to the drain electrode 164 of the driving transistor 160 to be applied with a driving voltage from the driving transistor 160 to drive the LED 170. In the meantime, even though in FIG. 4, it is illustrated that the connection pad CNT is not in direct contact with the drain electrode 164 of the driving transistor 160, but is in indirect contact therewith, the present disclosure is not limited thereto. Therefore, the connection pad CNT and the drain electrode 164 of the driving transistor 160 can be in direct contact with each other. Further, a low potential driving voltage can be applied to the first connection line 181 to drive the LED 170. Therefore, when the display device 100 is turned on, different voltage levels applied to the connection pad CNT and the first connection line 181 are transmitted to the n-electrode 174 and the p-electrode 175 so that the LED 170 can emit light.

The upper substrate 112 can cover various components disposed below the upper substrate 112. To be more specific, the upper substrate 112 is formed by coating a material which configures the upper substrate 112 on the lower substrate 111 and the first plate pattern 121 and then hardening the material to be in contact with the lower substrate 111, the first plate pattern 121, the second line pattern 122, and the connection lines 181 and 182.

The upper substrate 112 can be formed of the same material as the lower substrate 111. For example, the upper substrate 112 can be formed of a silicon rubber such as polydimethylsiloxane (PDMS) or an elastomer such as polyurethane (PU) or polytetrafluoroethylene (PTFE) and thus have a flexible property. However, the material of the upper substrate 112 is not limited thereto.

In the meantime, a polarization layer can be disposed on the upper substrate 112. The polarization layer can perform a function which polarizes light incident from the outside of the display device 100 to reduce the external light reflection. Further, an optical film other than the polarization layer can be disposed on the upper substrate 112.

According to the exemplary embodiment, the filling layer 190 can be disposed on the entire surface of the lower substrate 111 to be filled between the components disposed on the upper substrate 112 and the lower substrate 111. The filling layer 190 can be configured by a curable adhesive. Specifically, the material which configures the filling layer 190 is coated on the entire surface of the lower substrate 111 and then is cured so that the filling layer 190 can be disposed between the components disposed on the upper substrate 112 and the lower substrate 111. For example, the filling layer 190 can be an optically clear adhesive (OCA) and can be configured by an acrylic-based adhesive, a silicon-based adhesive, a urethane-based adhesive, and the like.

As described with reference to FIGS. 1 to 6, the display device 100 according to the exemplary embodiments of the present disclosure can be stretched with a structure including a lower substrate 111 and an upper substrate 112 which are flexible substrates and first line patterns 122 and connection lines 181 and 182 having a wavy shape.

Further, as described above, the gate driver GD included in the display device 100 according to the exemplary embodiments of the present disclosure is formed on the active area AA in the gate in array (GIA) manner so that a bezel area of the display device 100 can be minimized. As compared with the gate in panel (GIP) manner in which the gate driver is formed at the outside of the active area to supply a gate signal to the pixels, in the display device 100 according to the exemplary embodiments of the present disclosure, the gate driver GD is disposed in the center area CA of the active area AA in the gate in array (GIA) manner. Therefore, the gate signal delay according to the relative position of the pixel PX is minimized to improve the luminance uniformity of the entire active area AA so that the display device 100 with a high resolution and a large area can be implemented.

Hereinafter, a specific configuration of the gate driver GD included in the display device 100 according to the exemplary embodiments of the present disclosure, for example, a placement relationship and a cross-sectional structure of components included in the gate driver GD will be described in more detail with reference to FIGS. 7 to 11B.

FIG. 7 is a block diagram illustrating an example of a gate driver included in a display device of FIG. 1.

In the meantime, FIGS. 7 to 11B will be described based on an exemplary embodiment that the gate driver GD is a scan driver SD which supplies a scan signal SCAN (see FIG. 3) to pixels PX of the display device 100 which has been described with reference to FIGS. 1 to 6.

Further, for the convenience of description, in FIG. 7, four scan stages SST1 to SST4 included in the gate driver GD (hereinafter, a scan driver SD) and scan signals SCAN1 to SCAN4 output therefrom are illustrated.

Referring to FIG. 7, the scan driver SD can include a plurality of scan stages SST1 to SST4 (or a plurality of stages). The scan stages SST1 to SST4 are connected to corresponding scan signal lines (or gate signal lines) and output scan signals SCAN1 to SCAN4 (or gate signals) in response to the scan clock signals SCLK (or clock signals).

In one exemplary embodiment, the plurality of scan stages SST1 to SST4 included in the scan driver SD can be cascaded.

For example, the second scan stage SST2 is cascaded to the first scan stage SST1, the third scan stage SST3 is cascaded to the second scan stage SST2, and the fourth scan stage SST4 can be cascaded to the third scan stage SST3. Here, the plurality of scan stages SST1 to SST4 can have the substantially same configuration.

Each of the scan stages SST1 to SST4 can include a first input terminal 701, a second input terminal 702, a first power input terminal 703, a second power input terminal 704, and an output terminal 705.

The first input terminal 701 of each of the scan stages SST1 to SST4 can receive an input signal. For example, the first input terminal 701 of the first scan stage SST1 can receive a scan start signal SVST (or a gate start signal). Further, the first input terminal 701 of each of second to fourth scan stages SST2 to SST4 can receive a scan carry signal (for example, one of first to third scan carry signals SCR1 to SCR3, or a carry signal) output from an output terminal 705 of a previous stage. For example, the first input terminal 701 of the second scan stage SST2 receives a first scan carry signal SCR1 output from the output terminal 705 of the first scan stage SST1. The first input terminal 701 of the third scan stage SST3 receives a second scan carry signal SCR2 output from the output terminal 705 of the second scan stage SST2. The first input terminal 701 of the fourth scan stage SST4 can receive a third scan carry signal SCR3 output from the output terminal 705 of the third scan stage SST3.

The scan clock signals SCLK can be supplied to the second input terminal 702 of each of the scan stages SST1 to SST4. The scan clock signals SCLK can include a plurality of scan clock signals which has the same cycle and has a waveform in which phases do not overlap. Each of the scan stages SST1 to SST4 can receive at least one scan clock signal, among scan clock signals SCLK, through the second input terminal 702.

Voltages of power sources required to drive the scan stages SST1 to SST4 can be applied to the first and second power input terminals 703 and 704 of the scan stages SST1 to SST4.

For example, a voltage of the first power source VGH is applied to the first power input terminal 703 of each of the scan stages SST1 to SST4 and a voltage of the second power source VGL can be applied to the second power input terminal 704 of each of the scan stages SST1 to SST4. A voltage of the first power source VGH and a voltage of the second power source VGL have a DC voltage level. Here, a voltage level of the first power source VGH can be set to be higher than a voltage level of the second power source VGL.

Scan signals SCAN1 to SCAN4 can be output to the output terminals 705 of the scan stages SST1 to SST4. In one exemplary embodiment, scan signals SCAN1 to SCAN4 output to the output terminals 705 can be supplied to the corresponding emission signal line.

Further, the scan signals SCAN1 to SCAN4 output to the output terminals 705 of the scan stages SST1 to SST4 are scan carry signals SCR1 to SCR4 and can be supplied to the first input terminal 701 of a subsequent stage. For example, a first scan carries signal SCR1 output from the output terminal 705 of the first scan stage SST1 is supplied to the first input terminal 701 of the second scan stage SST2. A second scan carry signal SCR2 output from the output terminal 705 of the second scan stage SST2 is supplied to the first input terminal 701 of the third scan stage SST3. A third scan carry signal SCR3 output from the output terminal 705 of the third scan stage SST3 can be supplied to the first input terminal 701 of the fourth scan stage SST4.

In one exemplary embodiment, the scan stages SST1 to SST4 included in the scan driver SD can have the substantially same configuration, excluding a type of a signal which is received through the first input terminal 701. For example, the first scan stage SST1 which is a first stage which receives the scan start signal SVST through the first input terminal 701 and the remaining stages (for example, second to fourth scan stages SST2 to SST4) which receive the carry signal of the previous stage through the first input terminal 701 have the substantially same circuit configuration excluding an input signal (for example, the scan start signal SVST or a carry signal of the previous stage) which is received through the first input terminal 701 and can operate in the substantially same way.

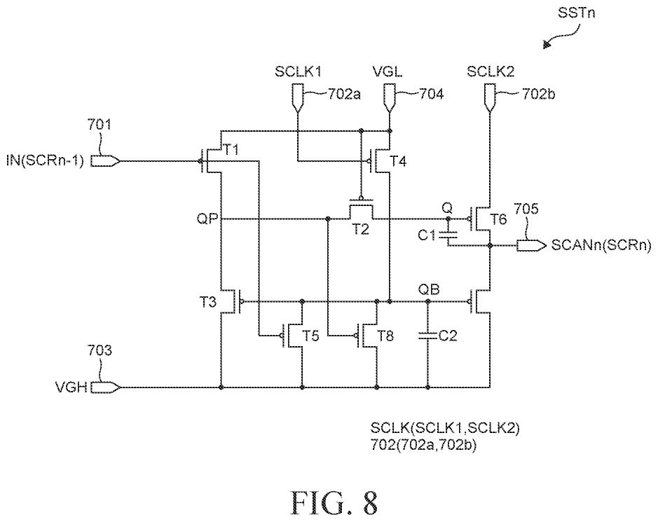

Accordingly, hereinafter, for the convenience of description, when the scan stages included in the scan driver SD is described, a configuration and a driving method of scan stages included in the scan driver SD will be described with respect to an n-th (n is an integer which is larger than 0) scan stage SSTn (see FIG. 8).

In the meantime, switch elements which configure each scan stage can be implemented by an n-type or a p-type MOSFET transistor. In the following exemplary embodiment, even though a p-type transistor is illustrated, but the exemplary embodiment of the present disclosure is not limited thereto.

Additionally, a transistor can be a three-electrode element including a gate electrode, a source electrode, and a drain electrode. The source electrode can be an electrode which supplies carriers to the transistor. In the transistor, the carriers can start flowing from the source electrode. The drain electrode can be an electrode through which the carriers are output from the transistor to the outside. Accordingly, the carrier in the MOSFET can flow from the source electrode to the drain electrode. In the case of the n-type MOSFET (NMOS), since the carriers are electrons, in order to allow the electrons to flow from the source electrode to the drain electrode, a voltage of the source electrode is lower than a voltage of the drain electrode. In the n-type MOSFET, since the electrons flow from the source electrode to the drain electrode, the current can flow from the drain electrode to the source electrode. In the case of the p-type MOSFET (PMOS), since the carriers are holes, in order to allow the holes to flow from the source electrode to the drain electrode, a voltage of the source electrode is higher than a voltage of the drain electrode. In the p-type MOSFET, since the holes flow from the source electrode to the drain electrode, the current can flow from the source electrode to the drain electrode. However, it should be noted that the source electrode and the drain electrode of the MOSFET are not fixed. For example, the source electrode and the drain electrode of the MOSFET can be changed depending on the applied voltage.

FIG. 8 is a circuit diagram illustrating an example of a stage included in a gate driver of FIG. 7.

Referring to FIGS. 7 and 8, the n-th scan stage SSTn included in the scan driver SD receives an input signal IN (for example, a n−1-th scan carry signal SCRn−1 output from the n−1-th scan stage which is a previous scan stage) through the first input terminal 701 and can receive scan clock signals SCLK through the second input terminal 702.

In one exemplary embodiment, the second input terminal 702 can include a first sub input terminal 702a and a second sub input terminal 702b. For example, the n-th scan stage SSTn receives the first scan clock signal SCLK1 through the first sub input terminal 702a and can receive the second scan clock signal SCLK2 through the second sub input terminal 702b.

Further, the n-th scan stage SSTn is connected to the first power source VGH through the first power input terminal 703 and can be connected to the second power source VGL through the second power input terminal 704.

In one exemplary embodiment, the n-th scan stage SSTn can generate and output the n-th scan signal SCANn (or the n-th scan carry signal SCRn) based on an input signal (for example, a n−1-th scan carry signal SCRn−1), the first scan clock signal SCLK1, the second scan clock signal SCLK2, a voltage of the first power source VGH, and a voltage of the second power source VGL.

To this end, the n-th scan stage SSTn can include first to eighth transistors T1 to T8, a first capacitor C1, and a second capacitor C2.

The first transistor T1 is connected between the second power input terminal 704 and a control node QP and can include a gate electrode connected to the first input terminal 701. The first transistor T1 is turned on when an input signal IN supplied through the first input terminal 701 has a gate-on level (for example, a low level) to electrically connect the second power input terminal 704 and the control node QP. When the first transistor T1 is turned on, a voltage of the second power source VGL which is supplied through the second power input terminal 704 can be supplied to the control node QP.

The second transistor T2 is connected between the control node QP corresponding to one electrode of the first transistor T1 and the first node Q and can include a gate electrode connected to the second power input terminal 704. The gate electrode of the second transistor T2 is connected to the second power input terminal 704 to which a voltage of the second power source VGL having a gate-on level (for example, a low level) is supplied so that the second transistor T2 can maintain a turned on state at all times. A voltage of the control node QP and a voltage of the first node Q can be maintained to be substantially the same by the second transistor T2 which maintains a turned-on state. For example, as described above, when the first transistor T1 is turned on so that the control node QP is electrically connected to the second power input terminal 704, the first node Q can be also electrically connected to the second power input terminal 704. For example, the second transistor T2 can serve as a bridge voltage transistor.

The third transistor T3 is connected between the first power input terminal 703 and a control node QP and can include a gate electrode connected to the second node QB. The third transistor T3 can be turned on or turned off based on a voltage of the second node QB.

For example, when the voltage of the second node QB has a gate-on level (for example, a low level), the third transistor T3 is turned on to electrically connect the first power input terminal 703 and the control node QP. In this case, a voltage of the first power source VGH of a gate-off level (for example, a high level) which is supplied to the first power input terminal 703 can be supplied to the control node QP.

In the meantime, as described above, the second transistor T2 always maintains a turned-on state so that when the third transistor T3 is turned on to electrically connect the control node QP to the first power input terminal 703, the first node Q can be also electrically connected to the first power input terminal 703.

The fourth transistor T4 is connected between the second power input terminal 704 and the second node QB and can include a gate electrode connected to the first sub input terminal 702a. The fourth transistor T4 is turned on when a first scan clock signal SCLK1 supplied through the first sub input terminal 702a has a gate-on level (for example, a low level) to electrically connect the second power input terminal 704 and the second node QB. In this case, a voltage of the second power source VGL of a gate-on level (for example, a low level) which is supplied to the second power input terminal 704 can be supplied to the second node QB.

The fifth transistor T5 is connected between the first power input terminal 703 and the second node QB and can include a gate electrode connected to the first input terminal 701. The fifth transistor T5 is turned on when an input signal IN supplied through the first input terminal 701 has a gate-on level (for example, a low level) to electrically connect the first power input terminal 703 and the second node QB. In this case, a voltage of the first power source VGH of a gate-off level (for example, a high level) which is supplied to the first power input terminal 703 can be supplied to the second node QB.

The sixth transistor T6 is connected between the second sub input terminal 702b and the output terminal 705 and can include a gate electrode connected to the first node Q. The sixth transistor T6 can be turned on or turned off by the voltage of the first node Q.

For example, when the voltage of the first node Q has a gate-on level (for example, a low level), the sixth transistor T6 is turned on to electrically connect the second sub input terminal 702b and the output terminal 705. Here, when the sixth transistor T6 is turned on, if the second scan clock signal SCLK2 supplied to the second sub input terminal 702b has a low level, the n-th scan signal SCANn (or the n-th scan carry signal SCRn) of the low level can be output through the output terminal 705.

The seventh transistor T7 is connected between the first power input terminal 703 and the output terminal 705 and can include a gate electrode connected to the second node QB. The seventh transistor T7 can be turned on or turned off by the voltage of the second node QB.

For example, when the voltage of the second node QB has a gate-on level (for example, a low level), the seventh transistor T7 is turned on to electrically connect the first power input terminal 703 and the output terminal 705. When the seventh transistor T7 is turned on, a high level of n-th scan signal SCANn (or the n-th scan carry signal SCRn) can be output through the output terminal 705.

As described above, the sixth transistor T6 of the n-th scan stage SSTn performs a pull-up function and the seventh transistor T7 of the n-th scan stage SSTn performs a pull-down function.

The eighth transistor T8 is connected between the first power input terminal 703 and the second node QB and can include a gate electrode connected to the control node QP. The gate electrode of the eighth transistor T8 can be connected to the first node Q via the second transistor T2. Here, as described above, the second transistor T2 always maintains a turned-on state so that a voltage of the gate electrode of the eighth transistor T8 and a voltage of the first node Q can be substantially maintained to be the same. For example, the eighth transistor T8 can be turned on or turned off according to the voltage of the first node Q.

For example, when the voltage of the first node Q has a gate-on level (for example, a low level), the eighth transistor T8 is turned on to electrically connect the first power input terminal 703 and the second node QB. When the eighth transistor T8 is turned on, the voltage of the first power source VGH of the gate-off level (for example, a high level) can be supplied to the second node QB.

The first capacitor C1 (or a boosting capacitor) can be connected between the first node Q and the output terminal 705. For example, the first capacitor C1 can include a first electrode connected to the first node Q and a second electrode connected to the output terminal 705.

The second capacitor C2 can be connected between the first power input terminal 703 and the second node QB. For example, the second capacitor C2 can include a first electrode connected to the first power input terminal 703 and a second electrode connected to the second node QB. Here, one electrode (for example, a first electrode) of the second capacitor C2 is connected to the first power input terminal 703 to which a voltage of the first power source VGH which is a constant power source is supplied so that the second capacitor C2 charges a voltage applied to the second node QB and can stably maintain a voltage of the second node QB.

In the meantime, as described with reference to FIGS. 1 to 6, the gate driver GD (for example, the scan driver SD) of the display device 100 according to the exemplary embodiments of the present disclosure can be disposed on the active area AA together with the plurality of pixels PX. To this end, components included in the stages of the gate driver GD (for example, the scan driver SD) need to be disposed on the active area AA (for example, the center area CA) so as not to overlap the plurality of pixels PX. Hereinafter, this will be described in more detail with reference to FIGS. 9 to 11B.

FIG. 9 is a view for explaining an example of a placement relationship between configurations included in a gate driver of FIG. 7.

In the meantime, in FIG. 9, for the convenience of description, components included in a n-th stage (for example, a n-th scan stage), among stages (for example, scan stages) of the gate driver GD (hereinafter, a scan driver SD) disposed in the center area CA of the active area AA (see FIG. 1), are illustrated.

In the meantime, for the convenience of description, in FIG. 9, eight pixels PX1 to PX8 are illustrated.

Referring to FIGS. 1 to 9, pixels PX1 to PX8 can be disposed to be spaced apart from each other. For example, as described with reference to FIGS. 1 to 6, pixels PX1 to PX8 can be disposed on the plurality of first plate patterns 121 disposed on the lower substrate 111 and is spaced apart from each other as island shapes. For example, in a first row R1 (for example, a n−1-th pixel row), first to fourth pixels PX1, PX2, PX3, and PX4 are sequentially disposed to be spaced apart from each other along the first direction X. In a second row R2 (for example, a n-th pixel row) adjacent to the first row R1, fifth to eighth pixels PX5, PX6, PX7, and PX8 can be sequentially disposed to be spaced apart from each other along the first direction X. As another example, in a first column C1, the first and fifth pixels PX1 and PX5 are spaced apart from each other to be sequentially disposed along a second direction Y. In a second column C2 adjacent to the first column C1, the second and sixth pixels PX2 and PX6 are spaced apart from each other to be sequentially disposed along the second direction Y. In a third column C3 adjacent to the second column C2, the third and seventh pixels PX3 and PX7 are spaced apart from each other to be sequentially disposed along the second direction Y. In a fourth column C4 adjacent to the third column C3, the fourth and eighth pixels PX4 and PX8 are spaced apart from each other to be sequentially disposed along the second direction Y.

The first to fourth pixels PX1, PX2, PX3, and PX4 disposed in the first row R1 (for example, the n−1-th pixel row) are supplied with a n−1-th scan signal through the n−1-th scan signal line, among the first connection lines 181. The fifth to eighth pixels PX5, PX6, PX7, and PX8 disposed in the second row R2 (for example, the n-th pixel row) are supplied with a n-th scan signal SCANn through the n-th scan signal line, among the first connection lines 181.

In the meantime, as described with reference to FIGS. 1 to 6, pixels PX1 to PX8 disposed on the first plate pattern 121 are electrically connected to the first line pattern 122 (see FIG. 1) and the connection lines 181 and 182 (see FIG. 2) to be supplied with various signals and various voltages. For example, various signals include a scan signal, an emission signal, a data signal, and the like and various voltages include a high potential voltage, a low potential voltage, an initialization voltage, and the like.

In one exemplary embodiment, the pattern layer 120 included in the display device 100 can further include the plurality of second plate patterns 123. The second plate patterns 123 can be disposed in the active area AA of the lower substrate 111. Components (for example, the first to eighth transistors T1 to T8 and the first and second capacitors C1 and C2) included in the n-th scan stage SSTn and connection signal lines 131, 132, and 133 which electrically connect the components can be disposed on the second plate pattern 123.

In one exemplary embodiment, each of the second plate patterns 123 can be disposed as islands shapes which are spaced apart from each other. The second plate patterns 123 can be individually separated. Accordingly, each of the second plate patterns 123 can be referred to as a second island pattern or a second individual pattern.

In one exemplary embodiment, each of the second plate patterns 123 can be disposed in an area between the first plate patterns 121 so as not to overlap the first plate patterns 121 in which the pixels PX1 to PX8 are disposed. Accordingly, the components (for example, the first to eighth transistors T1 to T8 and the first and second capacitors C1 and C2) included in the n-th scan stage SSTn formed on the second plate pattern 123 and the connection signal lines 131, 132, and 133 can be disposed and formed on the active area AA (or the center area CA) without overlapping the pixels PX1 to PX8 formed on the first plate pattern 121.

According to the exemplary embodiment, as illustrated in FIG. 9, sizes and shapes of the plurality of second plate patterns 123 can vary depending on a position in which the second plate pattern 123 is disposed. For example, the second plate pattern 123 disposed between two first plate patterns 121 which are adjacent to each other in the first direction X can have a rectangular shape with a longer side parallel to the second direction Y and a shorter side parallel to the first direction X. In contrast, the second plate pattern 123 disposed between two first plate patterns 121 which are adjacent to each other in the second direction Y can have a rectangular shape with a longer side parallel to the first direction X and a shorter side parallel to the second direction Y. Further, second plate patterns 123 which are diagonally alternately disposed with the first plate patterns 121 can have a square shape. However, this is just illustrative, so that sizes and shapes of the second plate patterns 123 are not limited thereto and the second plate patterns can be formed with various shapes.

According to the exemplary embodiment, as illustrated in FIG. 9, a sum of sizes of the plurality of second plate patterns 123 disposed for every unit area can be larger than a sum of sizes of the plurality of first plate patterns 121. As described above, components included in one scan stage (for example, the n-th scan stage SSTn) of the scan driver SD can be disposed in each of the second plate patterns 123. Here, an area occupied by various circuit configurations which configure one scan stage of the scan driver SD can be relatively larger than an area occupied by the pixels PX1 to PX8 so that the sum of sizes of the plurality of second plate patterns 123 disposed for every unit area can be larger than a sum of sizes of the plurality of first plate patterns 121.

In the exemplary embodiment in FIG. 9, the pattern layer 120 can further include a plurality of second line patterns 124 disposed in the active area AA.

The second line patterns 124 are patterns which are disposed in the active area AA and connect the second plate patterns 123 which are adjacent to each other and can be referred to as second connection patterns. For example, at least one second line pattern 124 can be disposed between the second plate patterns 124.

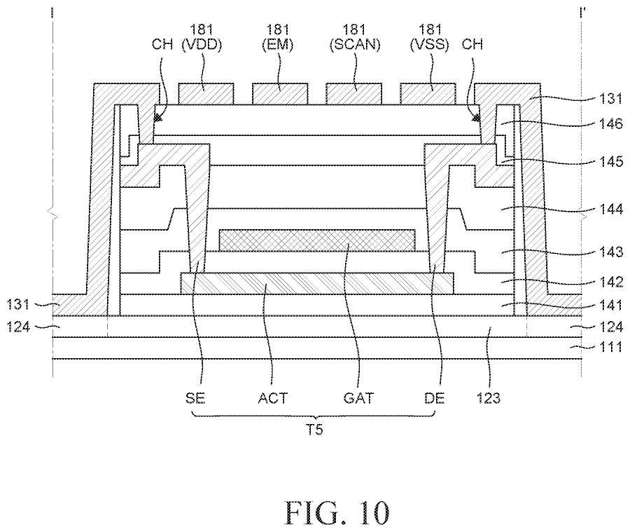

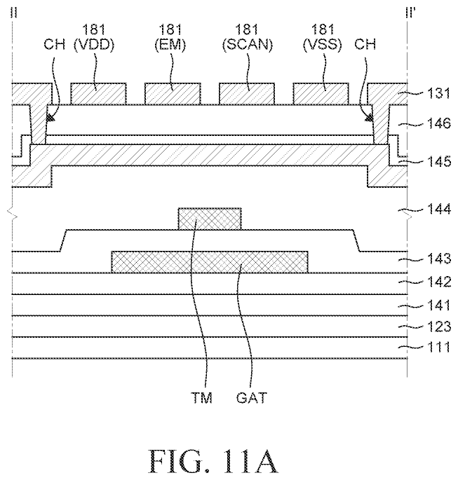

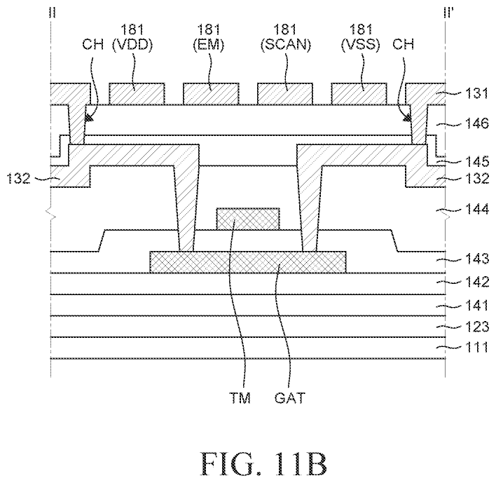

Each of the second line patterns 124 can be a line pattern disposed below the first connection signal line 131 disposed in an area between the second plate patterns 123. This will be described in more detail with reference to FIGS. 10 to 11B.

In one exemplary embodiment, the second plate pattern 123 and the second line pattern 124 can be rigid patterns. For example, the second plate pattern 123 and the second line pattern 124 can be more rigid than the lower substrate 111 and the upper substrate 112. Accordingly, moduli of elasticity of the second plate pattern 123 and the second line pattern 122 can be higher than the modulus of elasticity of the lower substrate 111. Therefore, the second plate pattern 123 and the second line pattern 124 can be referred to as a third rigid pattern and a fourth rigid pattern. For example, moduli of elasticity of the second plate pattern 123 and the second line pattern 124 can be 1000 times higher than the modulus of elasticity of the lower substrate 111 and the upper substrate 112, but it is illustrative, and the exemplary embodiment of the present disclosure is not limited thereto.

In the exemplary embodiment, the second plate pattern 123 and the second line pattern 124 can include a plastic material having a lower flexibility than the lower substrate 111 and the upper substrate 112. For example, the second plate pattern 123 and the second line pattern 124 can include at least one of polyimide (PI), polyacrylate, and polyacetate.

According to an exemplary embodiment, the second plate pattern 123 and the second line pattern 124 can be formed of the same material as the first plate pattern 121 and the first line pattern 122 described above, but is not limited thereto and can be formed of different materials.

The connection signal lines 131, 132, and 133 are disposed in the active area AA to supply various signals and various power voltages required to drive the scan stage of the scan driver SD.

The connection signal lines 131, 132, and 133 can be formed of a metal material such as copper (Cu), aluminum (Al), titanium (Ti), and molybdenum (Mo) or a stacked structure of metal materials such as copper/molybdenum-titanium (Cu/Moti) or titanium/aluminum/titanium (Ti/Al/Ti), but is not limited thereto.

In the exemplary embodiment, the first connection signal line 131 can be formed of the same material as the above-described connection lines 181 and 182, but is not limited thereto and can be formed of different materials.

In the exemplary embodiment, the first connection signal line 131 extends from an area in which the second plate patterns 123 are not disposed so that at least a part is formed on the second plate pattern 123 to be electrically connected to the second connection signal line 132 or the third connection signal line 133 formed on the second plate pattern 123 through a contact hole CH. For example, the first connection signal line 131 is disposed on the second line patterns 124 which connect the second plate pattern 123 or the first connection signal line 131 can be disposed on the second plate pattern 123.

In one exemplary embodiment, the second connection signal line 132 and the third connection signal line 133 can be formed on the second plate pattern 123. The second connection signal line 132 and the third connection signal line 133 are electrically connected to the first connection signal line 131 through the contact hole CH on the second plate pattern 123 to be supplied with various signals and various power voltages supplied from the first connection signal line 131.

Accordingly, the scan clock signals SCLK1 and SCLK2, the voltage of the first power source VGH, and the voltage of the second power source VGL supplied through the first connection signal line 131 can be supplied to the transistors T1 to T8 and the capacitors C1 and C2 included in the n-th scan stage SSTn, through the second connection signal line 132 or the third connection signal line 133, from the first connection signal line 131. The second connection signal line 132 or the third connection signal line 133 are electrically connected to the first connection signal line 131 through the contact hole CH.

In the meantime, for the convenience of description, even though in FIG. 9, the first connection signal line 131 is illustrated with a linear shape, the first connection signal lines 131 can have a wavy shape, which is substantially the same as or similar to the connection lines 181 and 182 which has been described with reference to FIG. 2. For example, the first connection signal line 131 can have a sinusoidal shape. However, it is just illustrative, so that the shape of the first connection signal lines 131 is not limited thereto. For example, each of the first connection signal lines 131 can have a zigzag shape. As another example, each of the first connection signal lines 131 can have various shapes, such as a plurality of rhombic substrates being connected and extending at vertices. As described above, the number and the shape of the plurality of first connection signal lines 131 illustrated in FIG. 9 are illustrative and the number and the shape of the plurality of first connection signal lines 131 can vary depending on the design.

In the exemplary embodiment, as described above, the transistors T1 to T8 and the capacitors C1 and C2 included in the n-th scan stage SSTn are disposed on the second plate pattern 123 to be connected to the second connection signal line 132 or the third connection signal line 133.

For example, the first transistor T1 can be disposed between the second pixel PX2 and the third pixel PX3. For example, the first transistor T1 can be disposed on the second plate pattern 123 disposed in the first row R1 and disposed between the second column C2 and the third column C3. The first electrode of the first transistor T1 is connected to the second connection signal line 132 to receive a voltage of the second power source VGL transmitted through the first connection signal line 131, the contact hole CH, and the second connection signal line 132. Further, the second connection signal line 132 which is connected to the second electrode of the first transistor T1 can be connected to the control node QP. Further, the gate electrode of the first transistor T1 is connected to the third connection signal line 133 to receive an input signal IN.

The second transistor T2 can be disposed between the third pixel PX3 and the seventh pixel PX7. For example, the second transistor T2 can be disposed on the second plate pattern 123 disposed in the third column C3 and disposed between the first row R1 and the second row R2. The second connection signal lines 132 which are connected to the first electrode and the second electrode of the second transistor T2 can be connected to the control node QP and the first node Q. Further, the gate electrode of the second transistor T2 is connected to the third connection signal line 133 to receive the voltage of the second power source VGL transmitted through the connection signal lines 131, 132, and 133 and a contact hole CH connecting them.

The third transistor T3 can be disposed between the second pixel PX2 and the sixth pixel PX6. For example, the third transistor T3 can be disposed on the second plate pattern 123 disposed in the second column C2 and disposed between the first row R1 and the second row R2. The first electrode of the third transistor T3 is connected to the second connection signal line 132 to receive a voltage of the first power source VGH transmitted through the first connection signal line 131, the contact hole CH, and the second connection signal line 132. Further, the second connection signal line 132 connected to the second electrode of the third transistor T3 is connected to the control node QP and the third connection signal line 133 connected to the gate electrode can be connected to the second node QB.

The fourth transistor T4 can be disposed between the first pixel PX1 and the fifth pixel PX5. For example, the fourth transistor T4 can be disposed on the second plate pattern 123 disposed in the first column C1 and disposed between the first row R1 and the second row R2. The first electrode of the fourth transistor T4 is connected to the second connection signal line 132 to receive a voltage of the second power source VGL transmitted through the first connection signal line 131, the contact hole CH, and the second connection signal line 132. Further, the second connection signal line 132 which is connected to the second electrode of the fourth transistor T4 can be connected to the second node QB. Further, the gate electrode of the fourth transistor T4 is connected to the third connection signal line 133 to receive the first scan clock signal SCLK1 which is transmitted through the first connection signal line 131, the second connection signal line 132, the third connection signal line 133, and the contact hole CH.

The fifth transistor T5 can be disposed between the first pixel PX1 and the second pixel PX2. For example, the fifth transistor T5 can be disposed on the second plate pattern 123 disposed in the first row R1 and disposed between the first column C1 and the second column C2. The first electrode of the fifth transistor T5 is connected to the second connection signal line 132 to receive a voltage of the first power source VGH transmitted through the first connection signal line 131, the contact hole CH, and the second connection signal line 132. Further, the second connection signal line 132 which is connected to the second electrode of the fifth transistor T5 can be connected to the second node QB. Further, the gate electrode of the fifth transistor T5 is connected to the third connection signal line 133 to receive an input signal IN.

The sixth transistor T6 can be disposed between the seventh pixel PX7 and the eighth pixel PX8. For example, the sixth transistor T6 can be disposed on the second plate pattern 123 disposed in the second row R2 and disposed between the third column C3 and the fourth column C4. The first electrode of the sixth transistor T6 is connected to the second connection signal line 132 to receive the second scan clock signal SCLK2 transmitted through the first connection signal line 131, the contact hole CH, and the second connection signal line 132. Further, the second electrode of the sixth transistor T6 is connected to the second connection signal line 132 to output the scan signal SCANn of the n-th scan stage SSTn through the second electrode of the sixth transistor T6. Further, the third connection signal line 133 which is connected to the gate electrode of the sixth transistor T6 can be connected to the first node Q.

The seventh transistor T7 can be disposed between the fifth pixel PX5 and the sixth pixel PX6. For example, the seventh transistor T7 can be disposed on the second plate pattern 123 disposed in the second row R2 and disposed between the first column C1 and the second column C2. The first electrode of the seventh transistor T7 is connected to the second connection signal line 132 to receive a voltage of the first power source VGH transmitted through the first connection signal line 131, the contact hole CH, and the second connection signal line 132. Further, the second electrode of the seventh transistor T7 is connected to the second connection signal line 132 to output the scan signal SCANn of the n-th scan stage SSTn through the second electrode of the seventh transistor T7. Further, the third connection signal line 133 which is connected to the gate electrode of the seventh transistor T7 can be connected to the second node QB.

The eighth transistor T8 can be disposed between the second pixel PX2 and the sixth pixel PX6. For example, the eighth transistor T8 can be disposed on the second plate pattern 123 disposed in the second column C2 and disposed between the first row R1 and the second row R2. The second connection signal line 132 connected to the first electrode of the eighth transistor T8 is connected to the second node QB and the third connection signal line 133 connected to the gate electrode can be connected to the control node QP. Further, the second electrode of the eighth transistor T8 is connected to the second connection signal line 132 to receive a voltage of the first power source VGH transmitted through the first connection signal line 131, the contact hole CH, and the second connection signal line 132.

Further, the first capacitor C1 can be disposed between the seventh pixel PX7 and the eighth pixel PX8. For example, the first capacitor C1 can be disposed on the second plate pattern 123 disposed in the second row R2 and disposed between the third column C3 and the fourth column C4.

The second capacitor C2 can be disposed between the fifth pixel PX5 and the sixth pixel PX6. For example, the second capacitor C2 can be disposed on the second plate pattern 123 disposed in the second row R2 and disposed between the first column C1 and the second column C2.

Hereinafter, a cross-sectional structure of the scan driver SD disposed on the active area AA will be described in more detail with reference to FIGS. 10 to 11B.

FIG. 10 is a cross-sectional view illustrating an example taken along line I-I′ of FIG. 9.

FIGS. 11A and 11B are cross-sectional views illustrating examples taken along line II-II′ illustrated in FIG. 9.

In the meantime, in FIGS. 10 to 11B, in order to avoid the redundant description, parts which will not be specifically described follow the above description and the same reference numeral denotes the same component and the similar reference numeral denotes the similar component.

Referring to FIGS. 1 to 10, the plurality of second plate patterns 123 disposed to be spaced apart from each other and the second line patterns 124 which connect the second plate patterns 123 can be disposed on the lower substrate 111 in the active area AA.

An inorganic insulating layer can be disposed on the plurality of second plate patterns 123. For example, the inorganic insulating layer can include a buffer layer 141, a gate insulating layer 142, a first interlayer insulating layer 143, a second interlayer insulating layer 144, and a passivation layer 145. However, the exemplary embodiment of the present disclosure is not limited thereto and various inorganic insulating layers are additionally disposed on the first plate patterns 121. At least one of the buffer layer 141, the gate insulating layer 142, the first interlayer insulating layer 143, the second interlayer insulating layer 144, and the passivation layer 145 which are inorganic insulating layers can be omitted.

To be more specific, the buffer layer 141 can be disposed on the second plate patterns 123. The buffer layer 141 can be configured by an insulating material. In one exemplary embodiment, the buffer layer 141 can be formed only in an area where the lower substrate 111 overlaps the first plate patterns 121 and the second plate patterns 123. As described above, the buffer layer 141 can be formed of an inorganic material so that the buffer layer 141 can be easily cracked or damaged during a process of stretching the display device 100. Therefore, the buffer layer 141 is not formed in an area between the first plate patterns 121 and the second plate patterns 123. Instead, the buffer layer 141 is patterned to have a shape of the first plate patterns 121 and the second plate patterns 123 to be formed only above the first plate patterns 121 and the second plate patterns 123. Therefore, in the display device 100 according to the exemplary embodiment of the present disclosure, the buffer layer 141 is formed only in an area overlapping the first plate patterns 121 and the second plate patterns 123 which are rigid patterns. Therefore, even though the display device 100 is bent or extended to be deformed, the damage of various components of the display device 100 can be suppressed.

A gate electrode GAT, an active layer ACT, a source electrode SE, and a drain electrode DE of a transistor (for example, the fifth transistor T5) which configures the scan stage SSTn can be disposed on the buffer layer 141.

First, the active layer ACT of the fifth transistor T5 can be disposed on the buffer layer 141. For example, the active layer ACT of the fifth transistor T5 can be formed of polycrystalline silicon (poly-Si). Alternatively, the active layer ACT of the fifth transistor T5 can be formed of oxide semiconductor, amorphous silicon (a-Si), organic semiconductor, or the like.

The gate insulating layer 142 can be disposed on the active layer ACT of the fifth transistor T5. The gate insulating layer 142 can electrically insulate the gate electrode GAT of the fifth transistor T5 from the active layer ACT. The gate insulating layer 142 can include an insulating material.

The gate electrode GAT of the fifth transistor T5 can be any one of various metal materials, for example, any one of molybdenum (Mo), aluminum (Al), chrome (Cr), gold (Au), titanium (Ti), nickel (Ni), neodymium (Nd), and copper (Cu) or an alloy of two or more of them, or a plurality of layers thereof, but it is not limited thereto.

The first interlayer insulating layer 143 can be disposed on the gate electrode GAT of the fifth transistor T5. The first interlayer insulating layer 143 can be formed of an inorganic material, similarly to the buffer layer 141.

The second interlayer insulating layer 144 can be disposed on the first interlayer insulating layer 143. The second interlayer insulating layer 144 can insulate the gate electrode GAT of the fifth transistor T5 from the source electrode SE and the drain electrode DE. The second interlayer insulating layer 144 can be formed of an inorganic material, which is the same as the buffer layer 141.

The source electrode SE and the drain electrode DE of the fifth transistor T5 can be disposed on the second interlayer insulating layer 144. The second interlayer insulating layer 144 can be formed of an inorganic material, which is the same as the buffer layer 141.

The source electrode SE and the drain electrode DE can include any one of various metal materials, for example, any one of molybdenum (Mo), aluminum (Al), chrome (Cr), gold (Au), titanium (Ti), nickel (Ni), neodymium (Nd), and copper (Cu) or an alloy of two or more of them, or a plurality of layers thereof, but it is not limited thereto.

In one exemplary embodiment, the second connection signal line 132 can be disposed on the same layer as a layer on which the source electrode SE and the drain electrode DE are disposed. For example, further referring to FIG. 11A, the second connection signal line 132 can be disposed on the same layer as a layer on which the source electrode SE and the drain electrode DE are disposed on the second plate pattern 123.

Referring to FIG. 10 again, the passivation layer 145 is disposed on the source electrode SE and the drain electrode DE. The passivation layer 145 can be formed of an inorganic material and configured by a single layer or a double layer, but is not limited thereto.

Further, the gate insulating layer 142, the first interlayer insulating layer 143, the second interlayer insulating layer 144, and the passivation layer 145 are patterned to be formed only in an area overlapping the plurality of second plate patterns 122. The gate insulating layer 142, the first interlayer insulating layer 143, the second interlayer insulating layer 144, and the passivation layer 145 are also formed of the inorganic material, similar to the buffer layer 141. Therefore, the gate insulating layer 142, the first interlayer insulating layer 143, the second interlayer insulating layer 144, and the passivation layer 145 can also be easily cracked to be damaged during the process of stretching the display device 100. Therefore, the gate insulating layer 142, the first interlayer insulating layer 143, the second interlayer insulating layer 144, and the passivation layer 145 are not formed in an area between the plurality of second plate patterns 122. However, the gate insulating layer 142, the first interlayer insulating layer 143, the second interlayer insulating layer 144, and the passivation layer 145 are patterned to have a shape of the plurality of second plate patterns 122 to be formed only above the second plate patterns 122.

The planarization layer 146 can be formed on the passivation layer 145. The planarization layer 146 can planarize an upper portion of the fifth transistor T5.

The first connection line 181 which has been described with reference to FIGS. 1 to 6 can be disposed on the planarization layer 146.

The first connection signal line 131 can be disposed on the second line pattern 124. Further, the first connection signal line 131 can extend onto the second plate patterns 123 to be electrically connected to the second connection signal lines 132 (or the third connection signal lines 133) on the second plate patterns 123. In the meantime, the second line pattern 124 is not disposed in an area where the first connection signal lines 131 are not disposed, among areas between the plurality of second plate patterns 123.

As described in FIG. 10, the first connection signal line 131 can be electrically connected to the source electrode SE or the drain electrode DE of a transistor (for example, the fifth transistor T5) through the contact hole CH on the second plate pattern 123.

Further, the first connection signal line 131 can be electrically connected to the second connection signal line 132 disposed on the second plate pattern 123 so as to extend to the second plate pattern 123 disposed in the other area on the second plate pattern 123, without being connected to the transistor (for example, the fifth transistor T5) disposed on the second plate pattern 123.

For example, referring to FIG. 11A, the first connection signal line 131 can be connected to the second connection signal line 132 which extends in one direction on the second plate pattern 123 through the contact hole CH.

As another example, referring to FIG. 11B, the first connection signal lines 131 are connected to the second connection signal lines 132 which are adjacent to each other through the contact hole CH on the second plate pattern 123. The second connection signal lines 132 which are adjacent to each other are connected to the gate electrode GAT through the contact hole which passes through the first and second interlayer insulating layers 143 and 144 to be connected to each other. However, this is just illustrative and the second connection signal lines 132 which are adjacent to each other are connected to an intermediate metal pattern TM through a contact hole which passes through the first interlayer insulating layer 143 to be connected to each other.

As described above with reference to FIGS. 1 to 11B, the gate driver GD (for example, the source driver SD) included in the display device 100 according to the exemplary embodiments of the present disclosure is formed on the active area AA in the gate in array (GIA) manner. Therefore, a bezel area of the display device 100 can be minimized. Further, in the display device 100 according to the exemplary embodiments of the present disclosure, the gate driver GD (for example, the source driver SD) is disposed in the center area CA of the active area AA in the gate in array (GIA) manner. Therefore, the gate signal delay according to the relative position of the pixel PX is minimized to improve the luminance uniformity of the entire active area AA so that the display device 100 with a high resolution and a large area can be implemented.

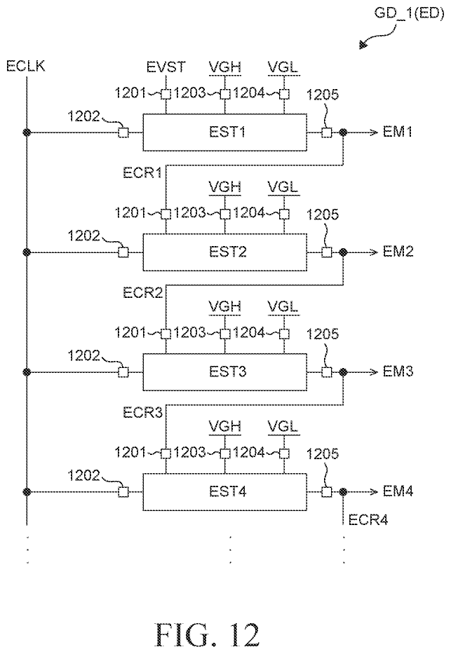

FIG. 12 is a block diagram illustrating another example of a gate driver included in a display device of FIG. 1.

In the meantime, FIGS. 12 to 14 will be described based on an exemplary embodiment that a gate driver GD_1 is an emission driver ED which supplies an emission signal EM (see FIG. 3) to pixels PX of the display device 100 which has been described with reference to FIGS. 1 to 6.

Further, for the convenience of description, in FIG. 12, four emission stages EST1 to EST4 included in the gate driver GD_1 (hereinafter, an emission driver ED) and emission signals EM1 to EM4 output therefrom are illustrated.

Referring to FIG. 12, the emission driver ED can include a plurality of emission stages EST1 to EST4 (or a plurality of stages). The emission stages EST1 to EST4 are connected to corresponding emission signal lines (or gate signal lines) and can output emission signals EM1 to EM4 (or gate signals) in response to the emission clock signals ECLK (or clock signals).

In one exemplary embodiment, the plurality of emission stages EST1 to EST4 included in the emission driver ED can be cascaded.

For example, the second emission stage EST2 is cascaded to the first emission stage EST1, the third emission stage EST3 is cascaded to the second emission stage EST2, and the fourth emission stage EST4 can be cascaded to the third emission stage EST3. Here, the plurality of emission stages EST1 to EST4 can have the substantially same configuration.

Each of the emission stages EST1 to EST4 can include a third input terminal 1201, a fourth input terminal 1202, a third power input terminal 1203, a fourth power input terminal 1204, and an output terminal 1205.

The third input terminal 1201 of each of the emission stages EST1 to EST4 can receive an input signal. For example, the third input terminal 1201 of the first emission stage EST1 can receive an emission start signal EVST (or a gate start signal). Further, the third input terminal 1201 of each of second to fourth emission stages EST2 to EST4 can receive an emission carry signal (for example, one of first to third emission carry signals ECR1 to ECR3, or a carry signal) output from an output terminal 1205 of a previous stage. For example, the third input terminal 1201 of the second emission stage EST2 receives a first emission carry signal ECR1 output from the output terminal 1205 of the first emission stage EST1. The third input terminal 1201 of the third emission stage EST3 receives a second emission carry signal ECR2 output from the output terminal 1205 of the second emission stage EST2. The third input terminal 1201 of the fourth emission stage EST4 can receive a third emission carry signal ECR3 output from the output terminal 1205 of the third emission stage EST3.

The emission clock signals ECLK can be supplied to the fourth input terminal 1202 of each of the emission stages EST1 to EST4. The emission clock signals ECLK can include a plurality of emission clock signals which has the same cycle and has a waveform in which phases do not overlap. Each of the emission stages EST1 to EST4 can receive at least one emission clock signal, among emission clock signals ECLK, through the fourth input terminal 1202.

Voltages of power sources required to drive the emission stages EST1 to EST4 can be applied to the first and second power input terminals 1203 and 1204 of the emission stages EST1 to EST4.

For example, a voltage of the first power source VGH is applied to the third power input terminal 1203 of each of the emission stages EST1 to EST4 and a voltage of the second power source VGL can be applied to the fourth power input terminal 1204 of each of the emission stages EST1 to EST4. A voltage of the first power source VGH and a voltage of the second power source VGL can have a DC voltage level. Here, a voltage level of the first power source VGH can be set to be higher than a voltage level of the second power source VGL.

Emission signals EM1 to EM4 can be output to the output terminals 1205 of the scan stages EST1 to EST4. In one exemplary embodiment, emission signals EM1 to EM4 output to the output terminals 1205 can be supplied to the corresponding scan signal line.

Further, the emission signals EM1 to EM4 output to the output terminals 1205 of the emission stages EST1 to EST4 are emission carry signals ECR1 to ECR4 and can be supplied to the third input terminal 1201 of a subsequent stage. For example, a first emission carry signal ECR1 output from the output terminal 1205 of the first emission stage EST1 is supplied to the third input terminal 1201 of the second emission stage EST2. A second emission carry signal ECR2 output from the output terminal 1205 of the second emission stage EST2 is supplied to the third input terminal 1201 of the third emission stage EST3. A third emission carry signal ECR3 output from the output terminal 1205 of the third emission stage EST3 can be supplied to the first input terminal 1205 of the fourth emission stage EST4.

In one exemplary embodiment, the emission stages EST1 to EST4 included in the emission driver ED can have the substantially same configuration, excluding a type of a signal which is received through the third input terminal 1201. For example, the first emission stage EST1 which is a first stage which receives the emission start signal EVST through the third input terminal 1201 and the remaining stages (for example, second to fourth emission stages EST2 to EST4) which receive the carry signal of the previous stage through the third input terminal 1201 have the substantially same circuit configuration excluding an input signal (for example, the emission start signal EVST or a carry signal of the previous stage) which is received through the third input terminal 1201 and operate in the substantially same way.

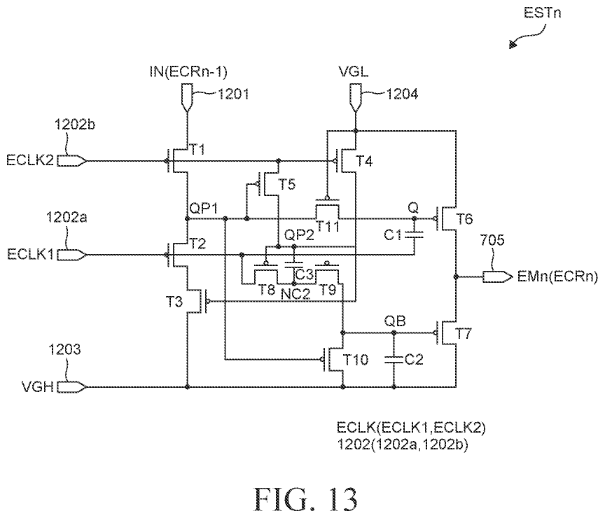

Accordingly, hereinafter, for the convenience of description, when the emission stages included in the emission driver ED is described, a configuration and a driving method of emission stages included in the emission driver ED will be described with respect to an n-th (n is an integer which is larger than 0) emission stage ESTn (see FIG. 13).

In the meantime, switch elements which configure each emission stage can be implemented by an n-type or a p-type MOSFET transistor. In the following exemplary embodiment, even though a p-type transistor is illustrated, but the exemplary embodiment of the present disclosure is not limited thereto.

FIG. 13 is a circuit diagram illustrating an example of a stage included in a gate driver of FIG. 12.

Referring to FIGS. 12 and 13, the n-th emission stage ESTn included in the emission driver ED receives an input signal IN (for example, a n−1-th emission carry signal SCRn−1 output from the n−1-th emission stage which is a previous emission stage) through the third input terminal 1201 and can receive emission clock signals ECLK through the second input terminal 702.

In one exemplary embodiment, the fourth input terminal 1202 can include a third sub input terminal 1202a and a fourth sub input terminal 1202b. For example, the n-th emission stage ESTn receives the first emission clock signal ECLK1 through the third sub input terminal 1202a and receives the second emission clock signal ECLK2 through the fourth sub input terminal 1202b.

Further, the n-th emission stage ESTn is connected to the first power source VGH through the third power input terminal 1203 and can be connected to the second power source VGL through the fourth power input terminal 1204.

In one exemplary embodiment, the n-th emission stage ESTn can generate and output the n-th emission signal EMn (or the n-th emission carry signal ECRn) based on an input signal (for example, a n−1-th emission carry signal ECRn−1), the first emission clock signal ECLK1, the second emission clock signal ECLK2, a voltage of the first power source VGH, and a voltage of the second power source VGL.

To this end, the n-th emission stage ESTn can include first to eleventh transistors T1 to T11, a first capacitor C1, a second capacitor C2, and a third capacitor C3.

The first transistor T1 is connected between the third input terminal 1201 and a first control node QP1 and can include a gate electrode connected to the fourth sub input terminal 1202b. The first transistor T1 is turned on when a second emission clock signal ECLK2 supplied through the fourth sub input terminal 1202b has a gate-on level (for example, a low level) to electrically connect the third input terminal 1201 and the first control node QP1.

The second transistor T2 is connected between the first control node QP1 corresponding to one electrode of the first transistor T1 and a first intermediate node NC1 corresponding to one electrode of the third transistor T3 and can include a gate electrode connected to the third sub input terminal 1202a. The second transistor T2 is turned on when a first emission clock signal ECLK1 supplied through the third sub input terminal 1202a has a gate-on level (for example, a low level) to electrically connect the first control node QP1 and the first intermediate node NC1.

The third transistor T3 is connected between the third power input terminal 1203 and the first intermediate node NC1 and can include a gate electrode connected to the second control node QP2. The third transistor T3 is turned on or turned off based on a voltage of the second control node QP2.

For example, when the voltage of the second control node QP2 has a gate-on level (for example, a low level), the third transistor T3 is turned on to electrically connect the third power input terminal 1203 and the intermediate node NC (or the second transistor T2). In this case, a voltage of the first power source VGH of a gate-off level (for example, a high level) which is supplied to the third power input terminal 1203 can be supplied to the first intermediate node NC1.

The fourth transistor T4 is connected between the fourth power input terminal 1204 and the second control node QP2 and can include a gate electrode connected to the fourth sub input terminal 1202b. The fourth transistor T4 is turned on when a second emission clock signal ECLK2 supplied through the fourth sub input terminal 1202b has a gate-on level (for example, a low level) to electrically connect the fourth power input terminal 1204 and the second control node QP2. In this case, a voltage of the second power source VGL of a gate-on level (for example, a low level) which is supplied to the fourth power input terminal 1204 can be supplied to the second control node QP2.

The fifth transistor T5 is connected between the fourth sub input terminal 1202b and the second control node QP2 and can be turned on or turned off based on the voltage of the first control node QP1.

The sixth transistor T6 is connected between the fourth power input terminal 1204 and the output terminal 1205 and can include a gate electrode connected to the first node Q. The sixth transistor T6 can be turned on or turned off based on a voltage of the first node Q.

For example, when the voltage of the first node Q has a gate-on level (for example, a low level), the sixth transistor T6 is turned on to electrically connect the fourth power input terminal 1204 and the output terminal 1205. When the sixth transistor T6 is turned on, a low level of n-th emission signal EMn (or the n-th emission carry signal ECRn) can be output through the output terminal 1205.

The seventh transistor T7 is connected between the third power input terminal 1203 and the output terminal 1205 and can include a gate electrode connected to the second node QB. The seventh transistor T7 can be turned on or turned off by the voltage of the second node QB.

For example, when the voltage of the second node QB has a gate-on level (for example, a low level), the seventh transistor T7 is turned on to electrically connect the third power input terminal 1203 and the output terminal 1205. When the seventh transistor T7 is turned on, a high level of n-th emission signal EMn (or the n-th emission carry signal ECRn) can be output through the output terminal 1205.

As described above, the sixth transistor T6 of the n-th emission stage ESTn performs a pull-up function and the seventh transistor T7 of the n-th emission stage ESTn performs a pull-down function.

The eighth transistor T8 is connected between the third sub input terminal 1202a and a second intermediate node NC2 which corresponds to one electrode of the ninth transistor T9 and can include a gate electrode connected to the second control node QP2. The eighth transistor T8 is turned on or turned off by the voltage of the second control node QP2.

The ninth transistor T9 is connected between the second intermediate node NC2 and the second node QB and can include a gate electrode connected to the third sub input terminal 1202a. The ninth transistor T9 is turned on when a first emission clock signal ECLK1 supplied through the third sub input terminal 1202a has a gate-on level (for example, a low level) to electrically connect the second intermediate node NC2 and the second node QB.

The tenth transistor T10 is connected between the third power input terminal 1203 and the second node QB and can include a gate electrode connected to the first control node QP1. The gate electrode of the tenth transistor T10 can be connected to the first node Q via the eleventh transistor T11. Here, to be described below, the eleventh transistor T11 always maintains a turned-on state so that voltage of the gate electrode of the tenth transistor T10 and the voltage of the first node Q are substantially maintained to be the same. For example, the tenth transistor T10 can be turned on or turned off according to the voltage of the first node Q.

For example, when the voltage of the first node Q has a gate-on level (for example, a low level), the tenth transistor T10 is turned on to electrically connect the third power input terminal 1203 and the second node QB. When the tenth transistor T10 is turned on, the voltage of the first power source VGH of the gate-off level (for example, a high level) is supplied to the second node QB.

The eleventh transistor T11 is connected between the first control node QP1 corresponding to one electrode of the first transistor T1 and the first node Q and can include a gate electrode connected to the fourth power input terminal 1204. The gate electrode of the eleventh transistor T11 is connected to the fourth power input terminal 1204 to which a voltage of the second power source VGL having a gate-on level (for example, a low level) is supplied so that the eleventh transistor T11 can maintain a turned-on state at all times. A voltage of the first control node QP1 and a voltage of the first node Q can be maintained to be substantially the same by the eleventh transistor T11 which maintains a turned-on state. For example, as described above, when the first transistor T1 is turned on so that the first control node QP1 is electrically connected to the third input terminal 1201, the first node Q is also electrically connected to the first input terminal 1201. For example, the eleventh transistor T11 can serve as a bridge voltage transistor.

The first capacitor C1 can be connected between the first node Q and the third sub input terminal 1202a. For example, the first capacitor C1 can include a first electrode connected to the first node Q and a second electrode connected to the third sub input terminal 1202a.

The second capacitor C2 can be connected between the third power input terminal 1203 and the second node QB. For example, the second capacitor C2 can include a first electrode connected to the third power input terminal 1203 and a second electrode connected to the second node QB. Here, one electrode (for example, a first electrode) of the second capacitor C2 is connected to the third power input terminal 1203 to which a voltage of the first power source VGH which is a constant power source is supplied so that the second capacitor C2 charges a voltage applied to the second node QB and can stably maintain a voltage of the second node QB.

The third capacitor C3 can be connected between the second control node QP2 and the second intermediate node NC2. For example, the third capacitor C3 can include a first electrode connected to the second control node QP2 and a second electrode connected to the second intermediate node NC2.

In the meantime, as described with reference to FIGS. 1 to 6 and 12, the gate driver GD_1 (for example, the emission driver ED) of the display device 100 according to the exemplary embodiments of the present disclosure can be disposed on the active area AA together with the plurality of pixels PX. To this end, components included in the stages of a gate driver GD_1 (for example, the emission driver ED) need to be disposed on the active area AA (for example, the center area CA) so as not to overlap the plurality of pixels PX. Hereinafter, this will be described in more detail with reference to FIGS. 12 to 14.

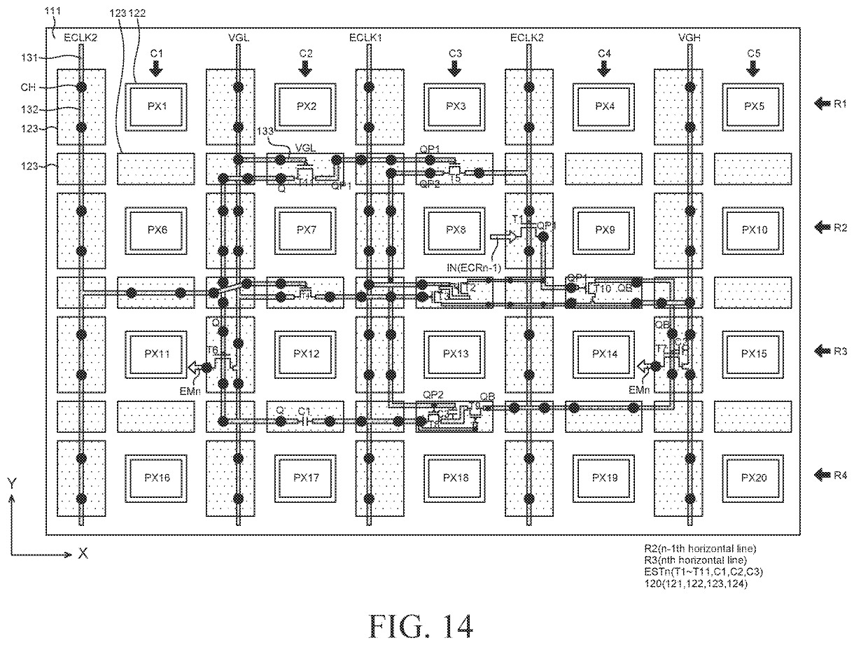

FIG. 14 is a view for explaining an example of a placement relationship between configurations included in a gate driver of FIG. 12.

In the meantime, in FIG. 14, for the convenience of description, components included in a n-th stage (for example, a n-th emission stage), among stages (for example, emission stages) of the gate driver GD_1 (hereinafter, an emission driver ED) disposed in the center area CA of the active area AA (see FIG. 1), are illustrated.

In the meantime, for the convenience of description, in FIG. 14, twenty pixels PX1 to PX20 are illustrated.

For the convenience of description, the repeated contents with the contents which have been described with reference to FIGS. 9 to 11B are not repeated. Parts which will not be specifically described follow the above description and the same reference numeral denotes the same component and the similar reference numeral denotes the similar component.

Referring to FIGS. 1 to 6 and 12 to 14, pixels PX1 to PX20 can be disposed to be spaced apart from each other. For example, the pixels PX1 to PX20 can be disposed on a plurality of first plate patterns 121 disposed on the lower substrate 111 and is spaced apart from each other to be disposed as island shapes.

For example, in the first row R1, first to fifth pixels PX1, PX2, PX3, PX4, and PX5 are spaced apart from each other to be sequentially disposed along the first direction X. In a second row R2 (for example, a n−1-th pixel row) which is adjacent to the first row R1, sixth to tenth pixels PX6, PX7, PX8, PX9, and PX10 are spaced apart from each other to be sequentially disposed along the first direction X. In the third row R3 (for example, a n-th pixel row) which is adjacent to the second row R2, eleventh to fifteenth pixels PX11, PX12, PX13, PX14, and PX15 are spaced apart from each other to be sequentially disposed along the first direction X. In a fourth row R4 which is adjacent to the third row R3, sixteenth to twentieth pixels PX16, PX17, PX18, PX19, and PX20 are spaced apart from each other to be sequentially disposed along the first direction X.

As another example, in a first column C1, first, sixth, eleventh, and sixteenth pixels PX1, PX6, PX11, and PX16 are spaced apart from each other to be sequentially disposed along the second direction Y. In a second column C2 which is adjacent to the first column C1, second, seventh, twelfth, and seventeenth pixels PX2, PX7, PX12, and PX17 are spaced apart from each other to be sequentially disposed along the second direction Y. In a third column C3 which is adjacent to the second column C2, third, eighth, thirteenth, and eighteenth pixels PX3, PX8, PX13, and PX18 are spaced apart from each other to be sequentially disposed along the second direction Y. In a fourth column C4 which is adjacent to the third column C3, fourth, ninth, fourteenth, and nineteenth pixels PX4, PX9, PX14, and PX19 are spaced apart from each other to be sequentially disposed along the second direction Y. In a fifth column C5 which is adjacent to the fourth column C5, fifth, tenth, fifteenth, and twentieth pixels PX5, PX10, PX15, and PX20 are spaced apart from each other to be sequentially disposed along the second direction Y.

The sixth to tenth pixels PX6, PX7, PX8, PX9, and PX10 disposed in the second row R2 (for example, the n−1-th pixel row) are supplied with a n−1-th emission signal through the n−1-th emission signal line, among the first connection lines 181. The eleventh to fifteenth pixels PX11, PX12, PX13, P14, and PX15 disposed in the third row R3 (for example, the n-th pixel row) are supplied with a n-th emission signal EMn through the n-th emission signal line, among the first connection lines 181.

In one exemplary embodiment, the pattern layer 120 included in the display device 100 can further include the plurality of second plate patterns 123. The second plate patterns 123 can be disposed in the active area AA of the lower substrate 111. Components (for example, the first to eleventh transistors T1 to T11 and the first to third capacitors C1, C2, and C3) included in the n-th emission stage ESTn and connection signal lines 131, 132, and 133 which electrically connect the components can be disposed on the second plate pattern 123.

In one exemplary embodiment, each of the second plate patterns 123 can be disposed in an area between the first plate patterns 121 so as not to overlap the first plate patterns 121 in which the pixels PX1 to PX20 are disposed. Accordingly, the components (for example, the first to eleventh transistors T1 to T11 and the first and second capacitors C1 and C2) included in the n-th emission stage ESTn formed on the second plate pattern 123 and the connection signal lines 131, 132, and 133 can be disposed and formed on the active area (or the center area CA) without overlapping the pixels PX1 to PX20 formed on the first plate patterns 121.

In the exemplary embodiment, as described with reference to FIGS. 1 to 11B, the pattern layer 120 is disposed in the active area AA and can further include a plurality of second line patterns and configured to connect the second plate patterns 123 which are adjacent.

The connection signal lines 131, 132, and 133 are disposed in the active area AA to supply various signals and various power voltages required to drive the emission stage of the emission driver ED. For example, the emission clock signals ECLK1 and ECLK2, the voltage of the first power source VGH, and the voltage of the second power source VGL supplied through the first connection signal line 131 are supplied to the transistors T1 to T11 and the capacitors C1, C2, and C3 included in the n-th emission stage ESTn, through the second connection signal line 132 or the third connection signal line 133, from the first connection signal line 131. The second connection signal line 132 or the third connection signal line 133 are electrically connected to the first connection signal line 131 through the contact hole CH.

In the exemplary embodiment, as described above, the transistors T1 to T11 and the capacitors C1, C2, and C3 included in the n-th emission stage ESTn are disposed on the second plate pattern 123 to be connected to the second connection signal line 132 or the third connection signal line 133.

For example, the first transistor T1 can be disposed between the eighth pixel PX8 and the ninth pixel PX9. For example, the first transistor T1 can be disposed on the second plate pattern 123 disposed in the second row R2 and disposed between the third column C3 and the fourth column C4. Further, the second connection signal line 132 which is connected to the first electrode of the first transistor T1 can be connected to the first control node QP1. Further, the second electrode of the first transistor T1 is connected to the second connection signal line 132 to receive an input signal IN. Further, the gate electrode of the first transistor T1 is connected to the third connection signal line 132 to receive the second emission clock signal ECLK1 which is transmitted through the first connection signal line 131, the second connection signal line 132, the third connection signal line 133, and the contact hole CH.

The second transistor T2 can be disposed between the eighth pixel PX8 and the thirteenth pixel PX13. For example, the second transistor T2 can be disposed on the second plate pattern 123 disposed in the third column C3 and disposed between the second row R2 and the third row R3. The second connection signal lines 132 which are connected to the first electrode and the second electrode of the second transistor T2 can be connected to the first control node QP1 and the first intermediate node NC1. Further, the gate electrode of the second transistor is connected to the third connection signal line 133 to receive the first emission clock signal ECLK1 through the first to third connection signal lines 131, 132, and 133 and the contact hole CH.

The third transistor T3 can be disposed between the eighth pixel PX8 and the thirteenth pixel PX13. For example, the third transistor T3 can be disposed on the second plate pattern 123 disposed in the third column C3 and disposed between the second row R2 and the third row R3. The first electrode of the third transistor T3 is connected to the second connection signal line 132 to receive a voltage of the first power source VGH transmitted through the first connection signal line 131, the second connection signal line 132, and the contact hole CH. Further, the second connection signal line 132 which is connected to the second electrode of the third transistor T3 can be connected to the first intermediate node NC. Further, the third connection signal line 133 which is connected to the gate electrode of the third transistor T3 can be connected to the second control node QP2.

The fourth transistor T4 can be disposed between the seventh pixel PX7 and the twelfth pixel PX12. For example, the fourth transistor T4 can be disposed on the second plate pattern 123 disposed in the second column C2 and disposed between the second row R2 and the third row R3. The first electrode of the fourth transistor T4 is connected to the second connection signal line 132 to receive a voltage of the second power source VGL2 transmitted through the first and second connection signal lines 131 and 132 and the contact hole CH. Further, the second connection signal line 132 which is connected to the second electrode of the fourth transistor T4 can be connected to the second control node QP2. Further, the gate electrode of the fourth transistor T4 is connected to the third connection signal line 133 to receive the second emission clock signal ECLK2 through the first to third connection signal lines 131, 132, and 133 and the contact hole CH.

The fifth transistor T5 can be disposed between the third pixel PX3 and the eighth pixel PX8. For example, the fifth transistor T5 can be disposed on the second plate pattern 123 disposed in the third column C3 and disposed between the first row R1 and the second row R2. The first electrode of the fifth transistor T5 is connected to the second connection signal line 132 to receive the second emission clock signal ECLK2 through the first and second connection signal lines 131 and 132 and the contact hole CH. Further, the second connection signal line 132 connected to the second electrode of the fifth transistor T5 and the third connection signal line 133 connected to the gate electrode can be connected to the second control node QP2 and the first control node QP1, respectively.

The sixth transistor T6 can be disposed between the eleventh pixel PX11 and the twelfth pixel PX12. For example, the sixth transistor T6 can be disposed on the second plate pattern 123 disposed in the third row R3 and disposed between the first column C1 and the second column C2. The first electrode of the sixth transistor T6 is connected to the second connection signal line 132 to receive a voltage of the second power source VGL transmitted through the first and second connection signal lines 131 and 132 and the contact hole CH. The second electrode of the sixth transistor T6 is connected to the second connection signal line 132 to output the emission signal EMn of the n-th emission stage ESTn through the second electrode of the sixth transistor T6. Further, the third connection signal line 133 which is connected to the gate electrode of the sixth transistor T6 can be connected to the first node Q.

The seventh transistor T7 can be disposed between the fourteenth pixel PX14 and the fifteenth pixel PX15. For example, the seventh transistor T7 can be disposed on the second plate pattern 123 disposed in the third row R3 and disposed between the fourth column C4 and the fifth column C5. The first electrode of the seventh transistor T7 is connected to the second connection signal line 132 to receive a voltage of the first power source VGH transmitted through the first and second connection signal lines 131 and 132 and the contact hole CH. The second electrode of the seventh transistor T7 is connected to the second connection signal line 132 to output the emission signal EMn of the n-th emission stage ESTn through the second electrode of the seventh transistor T7. Further, the third connection signal line 133 which is connected to the gate electrode of the seventh transistor T7 can be connected to the second node QB.

The eighth transistor T8 can be disposed between the thirteenth pixel PX13 and the eighteenth pixel PX18. For example, the eighth transistor T8 can be disposed on the second plate pattern 123 disposed in the third column C3 and disposed between the third row R3 and the fourth row R4. The first electrode of the eighth transistor T8 is connected to the second connection signal line 132 to receive the first emission clock signal ECLK1 through the first and second connection signal lines 131 and 132 and the contact hole CH. Further, the second connection signal line 132 connected to the second electrode of the eighth transistor T8 and the third connection signal line 133 connected to the gate electrode can be connected to the second intermediate node NC2 and the second control node QP2, respectively.

The ninth transistor T9 can be disposed between the thirteenth pixel PX13 and the eighteenth pixel PX18. For example, the ninth transistor T9 is disposed on the second plate pattern 123 disposed in the third column C3 and disposed between the third row R3 and the fourth row R4. The gate electrode of the ninth transistor T9 is connected to the first connection signal line 131 to receive the first emission clock signal ECLK1 through the first to third connection signal lines 132, 132, and 133 and the contact hole CH. The second connection signal lines 132 which are connected to the first electrode and the second electrode of the ninth transistor T9 can be connected to the second intermediate node NC2 and the second node QB.

The tenth transistor T10 can be disposed between the ninth pixel PX9 and the fourteenth pixel PX14. For example, the tenth transistor T10 can be disposed on the second plate pattern 123 disposed in the second row R2 and disposed between the third column C3 and the fourth column C4. The first electrode of the tenth transistor T10 is connected to the second connection signal line 132 to receive a voltage of the first power source VGH transmitted through the first and second connection signal lines 131 and 132 and the contact hole CH. Further, the second connection signal line 132 connected to the second electrode of the tenth transistor T10 and the third connection signal line 133 connected to the gate electrode can be connected to the second node QB and the first control node QP1, respectively.

The eleventh transistor T11 can be disposed between the second pixel PX2 and the seventh pixel PX7. For example, the eleventh transistor T11 can be disposed on the second plate pattern 123 disposed in the second column C2 and disposed between the first row R1 and the second row R2. The second connection signal lines 132 which are connected to the first electrode and the second electrode of the eleventh transistor T11 can be connected to the first node Q and the first control node QP1. Further, the third connection signal line 133 connected to the gate electrode of the eleventh transistor T11 can receive a voltage of the second power source VGL2 through the first and second connection signal lines 131 and 132 and the contact hole CH.

Further, the first capacitor C1 can be disposed between the twelfth pixel PX12 and the seventeenth pixel PX17. For example, the first capacitor C1 can be disposed on the second plate pattern 123 disposed in the second column C2 and disposed between the third row R3 and the fourth row R4.

The second capacitor C2 can be disposed between the fourteenth pixel PX14 and the fifteenth pixel PX15. For example, the second capacitor C2 can be disposed on the second plate pattern 123 disposed in the third row R3 and disposed between the fourth column C4 and the fifth column C5.

The third capacitor C3 can be disposed between the thirteenth pixel PX13 and the eighteenth pixel PX18. For example, the third capacitor C3 can be disposed on the second plate pattern 123 disposed in the third column C3 and disposed between the third row R3 and the fourth row R4.

The exemplary embodiments of the present disclosure can also be described as follows:

According to an aspect of the present disclosure, a display device can include a lower substrate which includes an active area and a non-active area and is stretchable; a pattern layer disposed on the active area of the lower substrate and including a plurality of first plate patterns and a plurality of first line patterns; a plurality of pixels disposed on each of the first plate patterns; a plurality of connection lines disposed on the first line patterns and configured to connect the pixels; and a gate driver which includes a plurality of stages to supply a gate signal to the pixels through the connection lines. The gate driver can be disposed on the active area of the lower substrate.

The pattern layer can further include a plurality of second plate patterns and a plurality of second line patterns, and each of the stages includes at least one transistor and at least one capacitor disposed on the second plate patterns.

The display device can further comprise a plurality of first connection signal lines disposed on the plurality of second line patterns and the plurality of second plate patterns; a plurality of second connection signal lines disposed on the second plate patterns; and a plurality of third connection signal lines disposed on the second plate patterns.

Each of the first connection signal lines can be electrically connected to at least one of the second connection signal lines and at least one of the third connection signal lines on the second plate pattern.

The second connection signal lines and the third connection signal lines can be electrically connected to at least one transistor and at least one capacitor included in the gate driver.

A power voltage and a signal which drive the gate driver can be transmitted to the first connection signal lines.

Each of the stages can include a first transistor which is connected between a second power input terminal supplied with a voltage of a second power source and a control node and includes a gate electrode connected to a first input terminal supplied with an input signal; a second transistor which is connected between the control node and a first node and includes a gate electrode connected to the second power input terminal; a third transistor which is connected between a first power input terminal supplied with a voltage of a first power source and the control node and includes a gate electrode connected to a second node; a fourth transistor which is connected between the second power input terminal and the second node and includes a gate electrode connected to a first sub input terminal supplied with a first clock signal; a fifth transistor which is connected between the first power input terminal and the second node and includes a gate electrode connected to the first input terminal; a sixth transistor which is connected between a second sub input terminal supplied with a second clock signal and an output terminal and includes a gate electrode connected to the first node; a seventh transistor which is connected between the first power input terminal and the output terminal and includes a gate electrode connected to the second node; an eighth transistor which is connected between the first power input terminal and the second node and includes a gate electrode connected to the control node; a first capacitor connected between the first node and the output terminal; and a second capacitor connected between the first power input terminal and the second node.

The pixels can include first to fourth pixels which are disposed in a first row and are sequentially disposed along first to fourth columns; and fifth to eighth pixels which are disposed in a second row adjacent to the first row and are sequentially disposed along the first to fourth columns.

The first transistor can be disposed on a second plate pattern disposed in the first row and disposed between the second column and the third column, among the second plate patterns and the third and eighth transistors are disposed on a second plate pattern disposed in the second column and disposed between the first row and the second row, among the second plate patterns.

The fourth transistor can be disposed on a second plate pattern disposed in the first column and disposed between the first row and the second row, among the second plate patterns and the fifth transistor is disposed on a second plate pattern disposed in the first row and disposed between the first column and the second column, among the second plate patterns.

The sixth transistor and the first capacitor can be disposed on a second plate pattern disposed in the second row and disposed between the third column and the fourth column, among the second plate patterns and the seventh transistor and the second capacitor are disposed on a second plate pattern disposed in the second row and disposed between the first column and the second column, among the second plate patterns.

Each of the stages can include a first transistor which is connected between a third input terminal supplied with an input signal and a first control node and includes a gate electrode connected to a fourth sub input terminal supplied with a second clock signal; a second transistor which is connected between the first control node and a first intermediate node and includes a gate electrode connected to a third sub input terminal supplied with a first clock signal; a third transistor which is connected between the first intermediate node and a third power input terminal supplied with a voltage of a first power source and includes a gate electrode connected to a second control node; a fourth transistor which is connected between a fourth power input terminal supplied with a voltage of a second power source and a second control node and includes a gate electrode connected to the fourth sub input terminal; a fifth transistor which is connected between the fourth sub input terminal and the second control node and includes a gate electrode connected to the first control node; a sixth transistor which is connected between the fourth power input terminal and the output terminal and includes a gate electrode connected to a first node; a seventh transistor which is connected between the third power input terminal and the output terminal and includes a gate electrode connected to a second node; an eighth transistor which is connected between the third sub input terminal and a second intermediate node and includes a gate electrode connected to the second control node; a ninth transistor which is connected between the second intermediate node and the second node and includes a gate electrode connected to the third sub input terminal; a tenth transistor which is connected between the third power input terminal and the second node and includes a gate electrode connected to the first control node; an eleventh transistor which is connected between the first control node and the first node and includes a gate electrode connected to the fourth power input terminal; a first capacitor connected between the first node and the third sub input terminal; a second capacitor connected between the first power input terminal and the second node; and a third capacitor connected between the second control node and the second intermediate node.

The pixels can include first to fifth pixels which are disposed in a first row and are sequentially disposed along first to fifth columns; sixth to tenth pixels which are disposed in a second row adjacent to the first row and are sequentially disposed along the first to fifth columns; eleventh to fifteenth pixels which are disposed in a third row adjacent to the second row and are sequentially disposed along the first to fifth columns; and sixteenth to twentieth pixels which are disposed in a fourth row adjacent to the third row and are sequentially disposed along the first to fifth columns.

The first transistor can be disposed on a second plate pattern disposed in the second row and disposed between the third column and the fourth column, among the second plate patterns and the second transistor and the third transistor are disposed on a second plate pattern disposed in the third column and disposed between the second row and the third row, among the second plate patterns.

The fourth transistor can be disposed on a second plate pattern disposed in the second column and disposed between the second row and the third row, among the second plate patterns and the fifth transistor is disposed on a second plate pattern disposed in the third column and disposed between the first row and the second row, among the second plate patterns.

The sixth transistor can be disposed on a second plate pattern disposed in the third row and disposed between the first column and the second column, among the second plate patterns and the first capacitor is disposed on a second plate pattern disposed in the second column and disposed between the third row and the fourth row, among the second plate patterns.

The seventh transistor and the second capacitor can be disposed on a second plate pattern disposed in the third row and disposed between the fourth column and the fifth column, among the second plate patterns and the eighth transistor, the ninth transistor, and the third capacitor are disposed on a second plate pattern disposed in the third column and disposed between the third row and the fourth row, among the second plate patterns.

The tenth transistor can be disposed on a second plate pattern disposed in the fourth column and disposed between the second row and the third row, among the second plate patterns.

The first plate patterns may not overlap the second plate patterns.

The connection lines and the first connection signal lines can include the same material.

Although the exemplary embodiments of the present disclosure have been described in detail with reference to the accompanying drawings, the present disclosure is not limited thereto and can be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

What is claimed is:

1. A display device, comprising:
a lower substrate including an active area and a non-active area, and being stretchable;
a pattern layer disposed on the active area of the lower substrate, and including a plurality of first plate patterns and a plurality of first line patterns;
a plurality of pixels disposed on each of the plurality of first plate patterns;
a plurality of connection lines disposed on the plurality of first line patterns, and configured to connect the plurality of pixels; and
a gate driver including a plurality of stages to supply a gate signal to the plurality of pixels through the plurality of connection lines,
wherein the gate driver is disposed on the active area of the lower substrate.

2. The display device according to claim 1, wherein the pattern layer further includes a plurality of second plate patterns and a plurality of second line patterns, and
each of the plurality of stages includes at least one transistor and at least one capacitor disposed on the plurality of second plate patterns.

3. The display device according to claim 2, further comprising:
a plurality of first connection signal lines disposed on the plurality of second line patterns and the plurality of second plate patterns;
a plurality of second connection signal lines disposed on the plurality of second plate patterns; and
a plurality of third connection signal lines disposed on the plurality of second plate patterns.

4. The display device according to claim 3, wherein each of the plurality of first connection signal lines is electrically connected to at least one of the plurality of second connection signal lines and at least one of the plurality of third connection signal lines on the plurality of second plate patterns.

5. The display device according to claim 4, wherein the plurality of second connection signal lines and the plurality of third connection signal lines are electrically connected to at least one transistor and at least one capacitor included in the gate driver.

6. The display device according to claim 5, wherein a power voltage and a signal which drive the gate driver are transmitted to the plurality of first connection signal lines.

7. The display device according to claim 2, wherein each of at least one of the plurality of stages includes:
a first transistor connected between a second power input terminal supplied with a voltage of a second power source and a control node, and including a gate electrode connected to a first input terminal supplied with an input signal;
a second transistor connected between the control node and a first node, and including a gate electrode connected to the second power input terminal;
a third transistor connected between a first power input terminal supplied with a voltage of a first power source and the control node, and including a gate electrode connected to a second node;
a fourth transistor connected between the second power input terminal and the second node, and including a gate electrode connected to a first sub input terminal supplied with a first clock signal;
a fifth transistor connected between the first power input terminal and the second node, and including a gate electrode connected to the first input terminal;
a sixth transistor connected between a second sub input terminal supplied with a second clock signal and an output terminal, and including a gate electrode connected to the first node;
a seventh transistor connected between the first power input terminal and the output terminal, and including a gate electrode connected to the second node;
an eighth transistor connected between the first power input terminal and the second node, and including a gate electrode connected to the control node;
a first capacitor connected between the first node and the output terminal; and
a second capacitor connected between the first power input terminal and the second node.

8. The display device according to claim 7, wherein the plurality of pixels include:
first to fourth pixels disposed in a first row and sequentially disposed along first to fourth columns; and
fifth to eighth pixels disposed in a second row adjacent to the first row and sequentially disposed along the first to fourth columns.

9. The display device according to claim 8, wherein the first transistor is disposed on a second plate pattern disposed in the first row and disposed between the second column and the third column, among the plurality of second plate patterns, and
the third and eighth transistors are disposed on a second plate pattern disposed in the second column and disposed between the first row and the second row, among the plurality of second plate patterns.

10. The display device according to claim 8, wherein the fourth transistor is disposed on a second plate pattern disposed in the first column and disposed between the first row and the second row, among the plurality of second plate patterns, and
the fifth transistor is disposed on a second plate pattern disposed in the first row and disposed between the first column and the second column, among the plurality of second plate patterns.

11. The display device according to claim 8, wherein the sixth transistor and the first capacitor are disposed on a second plate pattern disposed in the second row and disposed between the third column and the fourth column, among the plurality of second plate patterns, and
the seventh transistor and the second capacitor are disposed on a second plate pattern disposed in the second row and disposed between the first column and the second column, among the plurality of second plate patterns.

12. The display device according to claim 2, wherein each of the plurality of stages include:
a first transistor connected between a third input terminal supplied with an input signal and a first control node, and including a gate electrode connected to a fourth sub input terminal supplied with a second clock signal;
a second transistor connected between the first control node and a first intermediate node, and including a gate electrode connected to a third sub input terminal supplied with a first clock signal;
a third transistor connected between the first intermediate node and a third power input terminal supplied with a voltage of a first power source, and including a gate electrode connected to a second control node;
a fourth transistor connected between a fourth power input terminal supplied with a voltage of a second power source and a second control node, and including a gate electrode connected to the fourth sub input terminal;
a fifth transistor connected between the fourth sub input terminal and the second control node, and including a gate electrode connected to the first control node.
a sixth transistor connected between the fourth power input terminal and the output terminal, and including a gate electrode connected to a first node;
a seventh transistor connected between the third power input terminal and the output terminal, and including a gate electrode connected to a second node;
an eighth transistor connected between the third sub input terminal and a second intermediate node, and including a gate electrode connected to the second control node;
a ninth transistor connected between the second intermediate node and the second node, and including a gate electrode connected to the third sub input terminal.
a tenth transistor connected between the third power input terminal and the second node, and including a gate electrode connected to the first control node;
an eleventh transistor connected between the first control node and the first node, and including a gate electrode connected to the fourth power input terminal;
a first capacitor connected between the first node and the third sub input terminal;
a second capacitor connected between the first power input terminal and the second node; and
a third capacitor connected between the second control node and the second intermediate node.

13. The display device according to claim 12, wherein the plurality of pixels include:
first to fifth pixels disposed in a first row and sequentially disposed along first to fifth columns;
sixth to tenth pixels disposed in a second row adjacent to the first row and sequentially disposed along the first to fifth columns;
eleventh to fifteenth pixels disposed in a third row adjacent to the second row and sequentially disposed along the first to fifth columns; and
sixteenth to twentieth pixels disposed in a fourth row adjacent to the third row and sequentially disposed along the first to fifth columns.

14. The display device according to claim 13, wherein the first transistor is disposed on a second plate pattern disposed in the second row and disposed between the third column and the fourth column, among the plurality of second plate patterns, and
the second transistor and the third transistor are disposed on a second plate pattern disposed in the third column and disposed between the second row and the third row, among the plurality of second plate patterns.

15. The display device according to claim 13, wherein the fourth transistor is disposed on a second plate pattern disposed in the second column and disposed between the second row and the third row, among the plurality of second plate patterns, and
the fifth transistor is disposed on a second plate pattern disposed in the third column and disposed between the first row and the second row, among the plurality of second plate patterns.

16. The display device according to claim 13, wherein the sixth transistor is disposed on a second plate pattern disposed in the third row and disposed between the first column and the second column, among the plurality of second plate patterns, and
the first capacitor is disposed on a second plate pattern disposed in the second column and disposed between the third row and the fourth row, among the plurality of second plate patterns.

17. The display device according to claim 13, wherein the seventh transistor and the second capacitor are disposed on a second plate pattern disposed in the third row and disposed between the fourth column and the fifth column, among the plurality of second plate patterns, and
the eighth transistor, the ninth transistor, and the third capacitor are disposed on a second plate pattern disposed in the third column and disposed between the third row and the fourth row, among the plurality of second plate patterns.

18. The display device according to claim 13, wherein the tenth transistor is disposed on a second plate pattern disposed in the fourth column and disposed between the second row and the third row, among the plurality of second plate patterns.

19. The display device according to claim 2, wherein the plurality of first plate patterns do not overlap the plurality of second plate patterns.

20. The display device according to claim 3, wherein the plurality of connection lines and the plurality of first connection signal lines include a same material.
